(19) United States
(12) Patent Application Publication
(10) Pub. No.: US 2025/0131140 A1
(43) Pub. Date: Apr. 24, 2025

(54) COMPUTER-BASED SYSTEM/PLATFORM CONFIGURED FOR NETWORK ACCESSIBLE VIRTUALLY SIMULATED LOCATIONS AND METHODS OF USE THEREOF

(71) Applicant: Equilibria Group Inc., Kasilof, AK (US)

(72) Inventors: David Creighton, Kasilof, AK (US); Johan Van Cauwenberghe, Asheville, NC (US); Chalinda Weerasinghe, Anchorage, AK (US)

(73) Assignee: Equilibria Group Inc., Kasilof, AK (US)

(21) Appl. No.: 18/827,251

(22) Filed: Sep. 6, 2024

Related U.S. Application Data
(60) Provisional application No. 63/591,840, filed on Oct. 20, 2023.

(51) Int. Cl. G06F 30/13

(52) U.S. Cl. CPC G06F 30/13

(57) ABSTRACT

Systems and methods enable creating a virtual environment. The systems and methods include obtaining a digital layout representing a layout of a planned virtual space, and mapping one or more areas defined within the digital layout to simulated area(s) in the virtual space using a virtual space 3D coordinate system configured to dynamically resize the simulated space or the simulated area in response to user interaction. An activity associated with the simulated area is determined and an external integration associated with the activity is identified, the external integration having additional functionality associated with performing the activity. A digital object is generated in the simulated area corresponding to the external integration, the digital object including computer instruction associated with the external integration so as to integrate the additional function into the simulated area, and the simulated space is published for access via a computing device.

### CLAIM TO PRIORITY

This application claims priority to U.S. Provisional Application 63/591,840, titled “COMPUTER-BASED SYSTEM/PLATFORM CONFIGURED FOR NETWORK ACCESSIBLE VIRTUALLY SIMULATED LOCATIONS AND METHODS OF USE THEREOF” and filed on Oct. 20, 2023, which is incorporated herein by reference in its entirety.

### FIELD OF TECHNOLOGY

The present disclosure generally relates to computer-based platforms and/or systems configured for network accessible virtually simulated locations, including simulated buildings and structures located at virtually simulated locations in an extensible virtual environment on a network.

### BACKGROUND OF TECHNOLOGY

Existing browsers and/or other applications that allow users to access content and/or interact with other users generally rely on primarily text and image based interface paradigms. Such an approach limits a user's ability to discover new content and/or resources.

Network resources and/or users are typically isolated from one another, only connected through hyperlinks or direct accessed by URL. For example, when browsing the internet via a browser, when traversing web pages the user experience is interrupted as one web page is unloaded and another web page is loaded in its place.

### SUMMARY

In some aspects, the techniques described herein relate to a method including: receiving, by at least one processor, a simulation request including identifying a place to be simulated in a virtual environment; obtaining, by the at least one processor, at least one digital layout representing at least one layout of at least one area of a planned virtual space; mapping, by the at least one processor, at least one area defined within the at least one digital layout to at least one simulated area in the virtual space based at least in part on a virtual space 3D coordinate system so as to create a simulated space including at least one simulated layout corresponding to the at least one area of the planned space; wherein the virtual space 3D coordinate system is configured to dynamically resize at least one simulated space of the at least one simulated area in response to at least one user interaction with the simulated space; determining, by the at least one processor, at least one activity associated with the at least one simulated area; determining, by the at least one processor, at least one external integration associated with the at least one activity; wherein the at least one external integration includes at least one additional function associated with performing the at least one activity; generating, by the at least one processor, at least one digital object in at least one simulated area corresponding to the at least one external integration, the at least one digital object including at least one computer instruction associated with the at least one external integration so as to integrate the at least one additional function into the at least one simulated area; wherein the at least one digital object is configured to, upon interaction by a user in the virtual space, cause the at least one external integration to perform the at least one additional function associated with performing the at least one activity; and publishing, by the at least one processor, the simulated space for access via at least one computing device.

In some aspects, the techniques described herein relate to a method, further including: generating, by the least one processor, a plurality of digital objects in the virtual space based at least in part on the at least one layout; wherein the plurality of digital objects includes, but is not limited to, at least one of: furniture, decorations, fixtures, furnishings, a clothing rack, store shelving, a cash register, or a vending machine.

In some aspects, the techniques described herein relate to a method, wherein the at least one digital object corresponding to the at least one external integration includes at least one of: a cash register that integrates at least one payment service into the virtual space, a mobile chat bot that integrates at least one artificial intelligence based chat service into the virtual space, or at least one data analytics model that integrates at least one data analytics service for user behavior tracking into the virtual space.

In some aspects, the techniques described herein relate to a method, further including: determining, by the at least one processor, at least one digital object of the plurality of digital objects associated with the at least one activity; and modifying, by the at least one processor, the at least one digital object in the at least one simulated area to define the at least one external service integration so as to cause to appear that the at least one digital object provides the at least one software-as-a-service function.

In some aspects, the techniques described herein relate to a method, further including: generating, by the at least one processor, a plurality of graphical layers visually representing the virtual space according to the at least one digital layout and the virtual space coordinate system; wherein the plurality of graphical layers are configured to be dynamically rendered based at least in part on at least one computing so as to visually mix at least one portion of the virtual space with a physical view of the place.

In some aspects, the techniques described herein relate to a method, further including: determining, by the at least one processor, a view orientation of a user of the at least one computing device in the at least one space of the place; determining, by the at least one processor, at least one graphical layer associated with the at least one digital object in the at least on simulated space corresponding to the at least one space; positioning, on at least one display of the at least one computing device, by the at least one processor, the at least one graphical layer to align the at least one simulated space with the at least one space based at least in part on the view orientation; and rendering, by the at least one processor, the at least one graphical layer so as to superimpose the at least one digital object within the view orientation of the at least one space.

In some aspects, the techniques described herein relate to a method, further including: determining, by the at least one processor, a simulated user location within the virtual space associated with the at least one user location based at least in part on the mapping of the place locations to the simulated place locations; and generating, by the at least one processor, a simulated user location representation representing the simulated user location within the simulated building so as to reflect the at least one user location.

In some aspects, the techniques described herein relate to a method, further including: receiving, by the at least one processor, a location indication from at least one mobile device associated with the user.

In some aspects, the techniques described herein relate to a method, further including: mapping, by the at least one processor, a second location in the virtual environment based at least in part on a virtual environment 3D coordinate system so as to create a second place in the virtual environment.

In some aspects, the techniques described herein relate to a method, wherein the place includes a physical location of a commercial entity.

In some aspects, the techniques described herein relate to a system including: at least one processor in communication with at least one non-transitory computer-readable medium having software instructions stored thereon, wherein, upon execution of the software instructions, the at least one processor is configured to perform a method including: receiving, by at least one processor, a simulation request including identifying a place to be simulated in a virtual environment; obtaining, by the at least one processor, at least one digital layout representing at least one layout of at least one area of a planned virtual space; mapping, by the at least one processor, at least one area defined within the at least one digital layout to at least one simulated area in the virtual space based at least in part on a virtual space 3D coordinate system so as to create a simulated space including at least one simulated layout corresponding to the at least one area of the planned space; wherein the virtual space 3D coordinate system is configured to dynamically resize at least one simulated space of the at least one simulated area in response to at least one user interaction with the simulated space; determining, by the at least one processor, at least one activity associated with the at least one simulated area; determining, by the at least one processor, at least one external integration associated with the at least one activity; wherein the at least one external integration includes at least one additional function associated with performing the at least one activity; generating, by the at least one processor, at least one digital object in at least one simulated area corresponding to the at least one external integration, the at least one digital object including at least one computer instruction associated with the at least one external integration so as to integrate the at least one additional function into the at least one simulated area; wherein the at least one digital object is configured to, upon interaction by a user in the virtual space, cause the at least one external integration to perform the at least one additional function associated with performing the at least one activity; and publishing, by the at least one processor, the simulated space for access via at least one computing device.

In some aspects, the techniques described herein relate to a system, the method further including: generating a plurality of digital objects in the virtual space based at least in part on the at least one layout; wherein the plurality of digital objects includes at least one of: furniture, decorations, fixtures, furnishings, a clothing rack, store shelving, a cash register, or a vending machine.

In some aspects, the techniques described herein relate to a system, wherein the at least one digital object corresponding to the at least one external integration includes at least one of: a cash register that integrates at least one payment service into the virtual space, a mobile chat bot that integrates at least one artificial intelligence based chat service into the virtual space, or at least one data analytics model that integrates at least one data analytics service for user behavior tracking into the virtual space.

In some aspects, the techniques described herein relate to a system, the method further including: determining at least one digital object of the plurality of digital objects associated with the at least one activity; and modifying the at least one digital object in the at least one simulated area to define the at least one external service integration so as to cause to appear that the at least one digital object provides the at least one software-as-a-service function.

In some aspects, the techniques described herein relate to a system, the method further including: generating a plurality of graphical layers visually representing the virtual space according to the at least one digital layout and the virtual space coordinate system; wherein the plurality of graphical layers are configured to be dynamically rendered based at least in part on at least one computing so as to visually mix at least one portion of the virtual space with a physical view of the place.

In some aspects, the techniques described herein relate to a system, the method further including: determining a view orientation of a user of the at least one computing device in the at least one space of the place; determining at least one graphical layer associated with the at least one digital object in the at least on simulated space corresponding to the at least one space; positioning, on at least one display of the at least one computing device the at least one graphical layer to align the at least one simulated space with the at least one space based at least in part on the view orientation; and rendering the at least one graphical layer so as to superimpose the at least one digital object within the view orientation of the at least one space.

In some aspects, the techniques described herein relate to a system, the method further including: determining a simulated user location within the virtual space associated with the at least one user location based at least in part on the mapping of the place locations to the simulated place locations; and generating a simulated user location representation representing the simulated user location within the simulated building so as to reflect the at least one user location.

In some aspects, the techniques described herein relate to a system, the method further including: receiving a location indication from at least one mobile device associated with the user.

In some aspects, the techniques described herein relate to a system, the method further including: mapping a second location in the virtual environment based at least in part on a virtual environment 3D coordinate system so as to create a second place in the virtual environment.

In some aspects, the techniques described herein relate to a system, wherein the place includes a physical location of a commercial entity.

### BRIEF DESCRIPTION OF THE DRAWINGS

Various embodiments of the present disclosure can be further explained with reference to the attached drawings, wherein like structures are referred to by like numerals throughout the several views. The drawings shown are not necessarily to scale, with emphasis instead generally being placed upon illustrating the principles of the present disclosure. Therefore, specific structural and functional details disclosed herein are not to be interpreted as limiting, but merely as a representative basis for teaching one skilled in the art to variously employ one or more illustrative embodiments.

FIG. 1 is a block diagram of a 3D simulated space platform 100 in accordance with one or more embodiments of the present disclosure.

FIG. 2 depicts an illustrative core sub-platform 120 of the 3D simulated space platform 100 in accordance with one or more embodiment of the present disclosure.

FIG. 3 depicts an illustrative personnel sub-platform 130 of the 3D simulated space platform 100 in accordance with one or more embodiment of the present disclosure.

FIG. 4 depicts an illustrative user sub-platform 140 of the 3D simulated space platform 100 in accordance with one or more embodiment of the present disclosure.

FIG. 5 depicts a block diagram of an exemplary computer-based system and platform for the 3D simulated space platform 100 in accordance with one or more embodiments of the present disclosure.

FIG. 6 depicts a block diagram of another exemplary computer-based system and platform for the 3D simulated space platform 100 in accordance with one or more embodiments of the present disclosure.

FIG. 7 depicts illustrative schematics of an exemplary implementation of the cloud computing/architecture(s) in which embodiments of a system for the 3D simulated space platform 100 may be specifically configured to operate in accordance with some embodiments of the present disclosure.

FIG. 8 depicts illustrative schematics of another exemplary implementation of the cloud computing/architecture(s) in which embodiments of a system for the 3D simulated space platform 100 may be specifically configured to operate in accordance with some embodiments of the present disclosure.

### DETAILED DESCRIPTION

Various detailed embodiments of the present disclosure, taken in conjunction with the accompanying FIGs., are disclosed herein; however, it is to be understood that the disclosed embodiments are merely illustrative. In addition, each of the examples given in connection with the various embodiments of the present disclosure is intended to be illustrative, and not restrictive.

Throughout the specification, the following terms take the meanings explicitly associated herein, unless the context clearly dictates otherwise. The phrases “in one embodiment” and “in some embodiments” as used herein do not necessarily refer to the same embodiment(s), though it may. Furthermore, the phrases “in another embodiment” and “in some other embodiments” as used herein do not necessarily refer to a different embodiment, although it may. Thus, as described below, various embodiments may be readily combined, without departing from the scope or spirit of the present disclosure.

In addition, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the terms “and” and “or” may be used interchangeably to refer to a set of items in both the conjunctive and disjunctive in order to encompass the full description of combinations and alternatives of the items. By way of example, a set of items may be listed with the disjunctive “or”, or with the conjunction “and.” In either case, the set is to be interpreted as meaning each of the items singularly as alternatives, as well as any combination of the listed items.

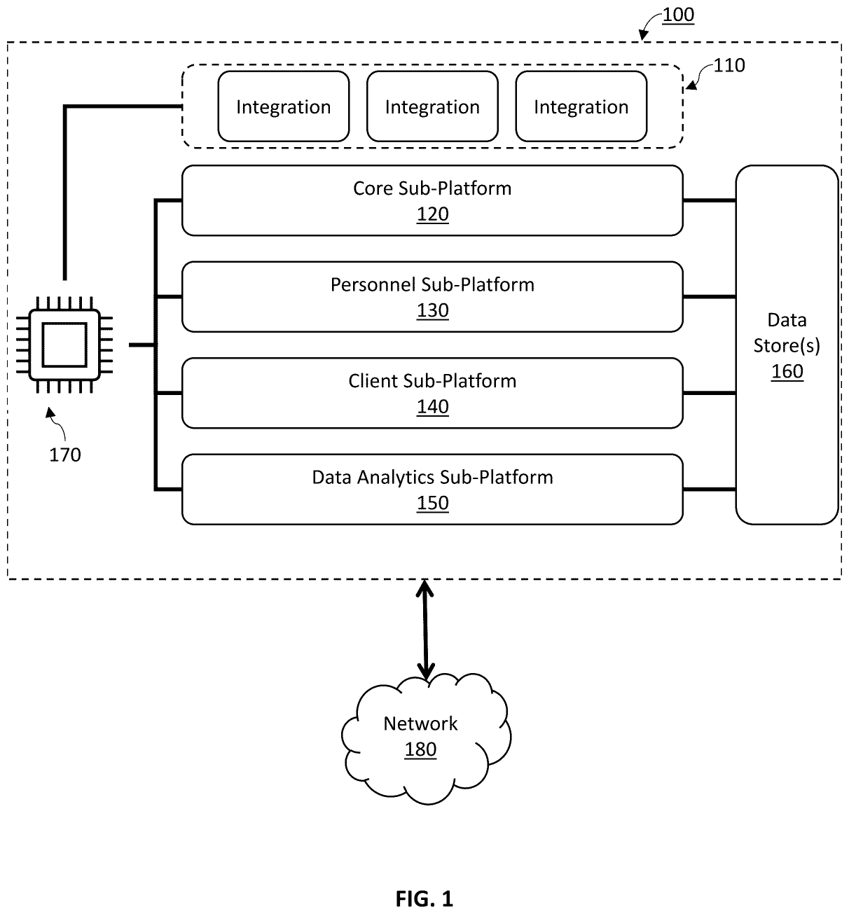

FIGS. 1 through 8 illustrate systems and methods of creating and rendering virtually simulated spaces and structures, including and not limited to real and/or virtual buildings, houses and other structures, as well as other physical and nonphysical locations. The following embodiments provide technical solutions and technical improvements that overcome technical problems, drawbacks and/or deficiencies in the technical fields involving three-dimensional (3D) model rendering, software service integration and display of user interfaces. As explained in more detail, below, technical solutions and technical improvements herein include aspects of improved rendering enabling a 3D model of a virtually simulated space and/or structure across two-dimensional (2D) and 3D displays in native application, web applications, and websites, as well as integrating multiple software services into virtual spaces and co-locating of multiple simulated spaces/structures in proximity to each other in a virtual location, thus improving on the user interface and hierarchical micro/macroverses in one or more communication networks. Based on such technical features, further technical benefits become available to users and operators of these systems and methods. Moreover, various practical applications of the disclosed technology are also described, which provide further practical benefits to users and operators that are also new and useful improvements in the art.

As online life and real-world or physical life blend together, shared experiences and life-like online experiences become increasingly more popular. However, it is not enough to simply create imagery of real-world things. Rather, the online world can be used to create deeper experiences in conjunction with the real-world through virtual simulations of real and imagined places that can augment real-world behaviors while extending the possibilities of community and experiences through the flexibility and extensibility of virtual spaces.

Embodiments herein provide extensible and flexible virtual spaces. Embodiments may use hierarchical coordinate systems to create a virtual environment in which multiple independent spaces may be placed, and which each space there may be multiple independent areas, where each area uses a separate area coordinate system within a space coordinate system, which itself is within an environment coordinate system. By using separate coordinate systems at different tiers of a hierarchy, each area and/or space need not be confined by the dimensions and/or size of other areas, spaces or the environment itself. Rather, each space in the environment may be presented to a user in the environment but outside of the spaces as having positions and/or sizes based on the environment coordinate system. But upon virtually entering a space, the user may be presented with a space that is sized and shaped independent from its appearance in the environment. Similarly, areas within the space may be presented according to the space coordinate system until entered, at which point the area may expand, contract or a combination thereof based on the area coordinate system of that area. Moreover, the user virtually entering an area or space may not remove another area or space from view, but rather maintain the relative positional relationship to the space or area that the user is in while the shape and/or size of the area changes.

Moreover, the coordinate systems may be dynamic coordinate systems where the size and/or shape may change based on the contents. The contents themselves may be dynamic based on the user, the time or day, day of the week, month of the year, administrator selection, or other factor or any combination thereof. Thus, in spaces and/or areas where digital items placed therein may vary, such as different store shelves, furniture, park or stage dimensions, or other digital items, the space and/or area may automatically expand or contract to fit the digital items. Such expansion or contraction may occur in real-time while a user is moving through the space/area, such as following a clothing rack that continually expands with additional offerings.

In some embodiments described herein, the spaces that appear within an environment and/or the areas that appear within a space may be dynamic based on the user, the time of day, the day of the week, the month of the year, an administrator selection, one or more integrations in an area or space, a user selection, among other factors or any combination thereof. To do so, relational mappings may be made between spaces, the relational mapping defining when and/or how two or more spaces are to appear in an environment together. The relational mappings may include conditional logic and/or machine learning inference to dynamically determine what spaces should appear in an environment together. For example, a user may navigate to a particular space associated with a particular entity, and may be presented with the exterior of the space in an environment. Based on the user and one or more recommendations crafted for that user, other spaces of interest may also appear in the environment. Alternatively, or in addition, the particular entity may have an agreement with another entity to be co-located, universally or under certain conditions, and thus the space of the other entity may appear in the environment along with the particular space of the particular entity.

The relational mappings may define relative positioning of spaces with respect to the environment coordinate system. For example, the relationship mappings may define that one space is to be the right, left, front, back, on top of, beneath or any combination thereof relative to another space in the environment. In some embodiments, the relational mappings may define specific environment coordinates at which each space is to be positioned, or the relational mappings may define relative positioning (e.g., units to the left, right, behind, in front, beneath, above, etc.) between spaces.

Embodiments described herein further provide for extensibility through integration of external or third-party functionality, such as additional platform integrations, services, networks, artificial intelligence, among others or any combination thereof. The integrations may include third-party provided digital items that are configured to interface with the third-party functionality, e.g., including via an actuator designed to trigger or call the third-party functionality upon user interaction. Thus, by positioning a third-party digital item within an environment, space and/or area, the interface to the third-party functionality may be integrated into the environment, space and/or area. To do so, templates may be defined on the platform that define the digital item, visual features of the digital item, one or more actuators for a user to interact with the digital item, one or more integrations with the third-party functionality, or other parameters or any combination thereof. Thus, as detailed herein, a template may be applied to a space and/or area to create an integration that visually is presented as the defined digital item with functionalities according to the defined actuators and/or integrated third-party functionalities and/or services. In some embodiments, the term “third-party” is used for ease of illustration but is not limited to entities other than an entity associated with the platform and/or sub-platform(s) and/or with a particular space, but rather may include any structures, functions, services, platforms, devices, systems, etc. that are not natively available via the platform and/or one or more sub-platforms detailed herein, regardless of whether such structures, functions, services, platforms, devices, systems, etc. are associated with the entity of the platform/sub-platform(s)/space.

Herein, the term “actuator” may refer to any interface element that a user may interact with to trigger a particular process, operation, task or other event or any combination thereof. An illustrative example of an actuator may include a button, but may include any one or more of other elements, such as a text input field, radio button, switch, virtual presence detection (e.g., of a user's avatar in proximity to the actuator), voice input, among others or any combination thereof.

FIG. 1 is a block diagram of a 3D simulated space platform 100 in accordance with one or more embodiments of the present disclosure.

In some embodiments, the 3D simulated space platform 100 may include multiple sub-platforms, along with data store(s) 160 and integrations 110, external and/or internal, to enable a user to create, host and deploy 3D representations of a structure, space, organization and/or location (collectively referred to throughout as “space”). Thus, the 3D simulated space platform 100 provides an ecosystem that empowers users, including individuals and/or organizations, to visually create a digital (real or imagined) representation of their space(s) that others users can transform to better engage with. In some embodiments, the 3D simulated space platform 100 is an immersive, integrated, expansive digital macrocosm with user-created microverses, all facilitating business and commercial exchange while providing user experiences that are otherwise unavailable.

Herein, the term “microverse” refers to a distinct 3D simulated space that may be stand-alone, combinable with other 3D simulated spaces, or a combination thereof. In some embodiments, the 3D simulated space platform 100 may enable the 3D simulated space for a user to be hosted on a network 180 for access via a web browser and/or a native application. For example, in some embodiments, the 3D simulated space platform 100 may be hosted in a cloud environment, on servers, on one or more computing devices, in a distributed computing system or any other suitable compute resource architecture or any combination thereof.

In some embodiments, terms “cloud,” “Internet cloud,” “cloud computing,” “cloud architecture,” and similar terms correspond to at least one of the following: (1) a large number of computers connected through a real-time communication network 180 (e.g., Internet); (2) providing the ability to run a program or application on many connected computers (e.g., physical machines, virtual machines (VMs)) at the same time; (3) network 180-based services, which appear to be provided by real server hardware, and are in fact served up by virtual hardware (e.g., virtual servers), simulated by software running on one or more real machines (e.g., allowing to be moved around and scaled up (or down) on the fly without affecting the end user). The aforementioned examples are, of course, illustrative and not restrictive.

In some embodiments, the network 180 may include any suitable computer network 180, including, two or more computers that are connected with one another for the purpose of communicating data electronically. In some embodiments, the network 180 may include a suitable network 180 type, such as, e.g., a public switched telephone network 180 (PTSN), an integrated services digital network 180 (ISDN), a private branch exchange (PBX), a wireless and/or cellular telephone network 180, a computer network 180 including a local-area network 180 (LAN), a wide-area network 180 (WAN) or other suitable computer network 180, or any other suitable network 180 or any combination thereof. In some embodiments, a LAN may connect computers and peripheral devices in a physical area by means of links (wires, Ethernet cables, fiber optics, wireless such as Wi-Fi, etc.) that transmit data. In some embodiments, a LAN may include two or more personal computers, printers, and high-capacity disk-storage devices, file servers, or other devices or any combination thereof. LAN operating system software, which interprets input and instructs networked devices, may enable communication between devices to: share the printers and storage equipment, simultaneously access centrally located processors, data, or programs (instruction sets), and other functionalities. Devices on a LAN may also access other LANs or connect to one or more WANs. In some embodiments, a WAN may connect computers and smaller networks 180 to larger networks 180 over greater geographic areas. A WAN may link the computers by means of cables, optical fibers, or satellites, cellular data networks 180, or other wide-area connection means. In some embodiments, an example of a WAN may include the Internet.

In some embodiments, the 3D simulated space platform 100 may advance the graphical user interface used in online interactions with one or more network locations, such as websites and social media, to enrich the relationships users, business owners, managers, employees, and customers, both current and potential, have to people, companies and other organizations, while empowering them to engage utilizing the latest in interactive hardware technologies, such as virtual reality headsets, desktop and mobile devices. The advanced graphic user interface may be in the form of 2D and/or 3D rendering of a 3D simulated space having dynamic and configurable spatial relationships with other network locations and 3D simulated spaces.

In some embodiments, the 3D simulated space platform 100 may merge and incorporate visual gaming advancements, such as one or more graphics engines and capabilities such as ray tracing to render 3D simulated spaces. In some embodiments, built into the 3D simulated space may be 3D representations of integrations 110 with software services, such as software business support services to make such software services structural components within the 3D simulated space. In some embodiments, the 3D simulated space platform 100 may further augment the integrations 100 and/or 3D simulated space with advanced artificial intelligence (AI) and analytical capabilities, to enhance business interactions around multiple areas of operations. The 3D simulated space platform 100 ecosystem may feature multiple platforms and sub-platforms that cater multiple demographics of users central to business, and offer businesses every traditional business enterprise resource in addition to interactive AI-driven capabilities. In some embodiments, one other such platform or sub-platform may include a distributed ledger network, such as a blockchain, for implementing a native token to the ecosystem, allowing for ecosystem-wide and/or microverse-specific crypto-tokens for use to create non-fungible items and assets in the 3D simulated space, such as a cryptocurrency and/or non-fungible token (NFT) for 3D simulated commerce and ownership of in-world items.

In some embodiments, the 3D simulated space platform 100 may include hardware components such as a processor(s) 170, which may include local or remote processing components. In some embodiments, the processor(s) 170 may include any type of data processing capacity, such as a hardware logic circuit, for example an application specific integrated circuit (ASIC) and a programmable logic, or such as a computing device, for example, a microcomputer or microcontroller that include a programmable microprocessor. In some embodiments, the processor(s) 170 may include data-processing capacity provided by the microprocessor. In some embodiments, the microprocessor may include memory, processing, interface resources, controllers, and counters. In some embodiments, the microprocessor may also include one or more programs stored in memory.

Similarly, the 3D simulated space platform 100 may include data store(s) 160, such as one or more local and/or remote data storage solutions such as, e.g., local hard-drive, solid-state drive, flash drive, database or other local data storage solutions or any combination thereof, and/or remote data storage solutions such as a server, mainframe, database or cloud services, distributed database or other suitable data storage solutions or any combination thereof. In some embodiments, the data store(s) 160 may include, e.g., a suitable non-transient computer readable medium such as, e.g., random access memory (RAM), read only memory (ROM), one or more buffers and/or caches, among other memory devices or any combination thereof.

In some embodiments, the 3D simulated space platform 100 may implement computer sub-platforms for implementing various aspects of the ecosystem of microverses. In some embodiments, the terms “platform”, “computer sub-platform” and “sub-platform” identify at least one software component and/or a combination of at least one software component and at least one hardware component which are designed/programmed/configured to manage/control other software and/or hardware components (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

In some embodiments, sub-platforms 120, 130, 140 and/or 150 may include dedicated and/or shared software components, hardware components, or a combination thereof. For example, the sub-platforms 120, 130, 140 and/or 150 may each include a dedicated processor and storage. However, in some embodiments, the sub-platforms 120, 130, 140 and/or 150 may share hardware resources, including the processor(s) 170 and data store(s) 160 of the 3D simulated space platform 100 via, e.g., a bus, orchestrator, and/or other infrastructure or any combination thereof.

In some embodiments, the sub-platforms of the 3D simulated space platform 100 may include four or more sub-platforms, including, e.g., a core sub-platform 120, a personnel sub-platform 130, a user sub-platform 140 and/or a data analytics sub-platform 150. In some embodiments, the sub-platforms 120 through 150 may interoperate to enable functionality in the 3D simulated space. In some embodiments, the sub-platforms 120 through 150 may interoperate using one or more hardware and/or software interfaces.

In some embodiments, one or more interfaces may utilize one or more software computing interface technologies, such as, e.g., Common Object Request Broker Architecture (CORBA), an application programming interface (API) and/or application binary interface (ABI), among others or any combination thereof. In some embodiments, an API and/or ABI defines the kinds of calls or requests that can be made, how to make the calls, the data formats that should be used, the conventions to follow, among other requirements and constraints. An “application programming interface” or “API” can be entirely custom, specific to a component, or designed based on an industry-standard to ensure interoperability to enable modular programming through information hiding, allowing users to use the interface independently of the implementation. In some embodiments, CORBA may normalize the method-call semantics between application objects residing either in the same address-space (application) or in remote address-spaces (same host, or remote host on a network).

In some embodiments, one or more interfaces may utilize one or more hardware computing interface technologies, such as, e.g., Universal Serial Bus (USB), IEEE 1394 (FireWire), Ethernet, Thunderbolt™, Serial ATA (SATA) (including eSATA, SATAe, SATAp, etc.), among others or any suitable combination thereof.

In some embodiments, the 3D simulated space platform 100 may implement the sub-platforms 120 through 150 to enable, for example, a business to create a 3D simulated space that users can access, navigate and interact with via 2D and/or 3D interface elements. In some embodiments, the user behaviors may be logged, e.g., in the data store(s) 160, to build interest profiles for each user for advertising, product and sales analytics, among other uses. Moreover, based on the user data, the 3D simulated space platform 100 may provide artificial intelligence (AI) to provide help and/or suggestions during user activity within the 3D simulated space. The AI may take the form of a disembodied voice, an avatar, a chat window, or other interface element presented in 2D, 3D or any combination thereof.

In some embodiments, the 3D simulated space platform 100 may enable multiple entities, such as multiple businesses to connect and co-locate their respective 3D simulated spaces in a larger space, termed a “microverse”, such that each 3D simulated space in the microverse may appear in proximity to each other in a simulated or virtual location such as a shopping mall, street, city block, or other environment or any combination thereof. Thus, users may access the microverse and engage with multiple stores, users, entities or other things or any combination thereof. In some embodiments, the virtual location may be associated with a real-world location or not, and may be linked to one or more other virtual locations to enable navigation to other microverses and other groups of 3D simulated spaces.

In some embodiments, a microverse may be specific to a user, such that a user navigating a 3D simulated space does so within a particular user-specific microverse having a coordinate system within the hierarchical coordinate systems detailed below, and/or objects situated within the 3D simulated space that are personalized to the user. In some embodiments, a user's microverse may be combined with other microverses of other users to create a macroverse, e.g., as detailed below using the hierarchical coordinate systems, allowing users to move between and/or merge microverses with others. In some embodiments, the microverse may be location or 3D simulated space specific for any user that may be present in the 3D simulated space. Thus, microverses may be defined according to coordinate systems in the hierarchical coordinate system based on which locations are within a larger coordinate system. In some embodiments, the microverse may have one or more other structures or any combination of the above.

In some embodiments, the core sub-platform 120 may include tools and features configured to owners/employees/businesses associated with the 3D virtual space. In some embodiments, such tools and features may include, e.g., customer focused tools, retail focused tools, business management focused tools, and/or business employee-focused tools, among others or any combination thereof.

In some embodiments, the core sub-platform 120 may include customer focused features that enable interface design facing a type of user that engages with a business associated with a 3D simulated space. In some embodiments, the customer-focused features may include a tool to create a store front of the 3D simulated space, along with products and/or servers being sold, advertised, referenced, linked, or otherwise virtually located within the store of the 3D simulated space.

In some embodiments, the core sub-platform 120 may include structural and functional features that may serve as a foundation for other sub-platforms to extend with additional and/or modular structures and/or features. For example, the core sub-platform 120 may include functionality for defining the spaces, layouts, contents of spaces, user tracking, visualization, or other spatial and/or user behavior functionality or any combination thereof. For example, the core sub-platform 120 may provide integration, e.g., via plug-ins, add-ons, extensions, cloud services, or other integrations 110 to augment the core sub-platform 120 functionality with external software and/or services, such as customer browsing, sales, engagement, and other uses. For example, the core sub-platform 120 may integrated with customer support personnel via avatars, text prompts, chat windows, or other interface elements which may appear as 2D and/or 3D interface elements within the 3D simulated space. In another example, the core sub-platform 120 may integrated with research tools, such as a price comparison tool, payment service, dictionary or encyclopedia, Wikipedia, internet search, among other tools or any combination thereof which may similarly appear as 2D and/or 3D interface elements within the 3D simulated space. The interface elements may appear as an overlay, a floating window, a 3D virtual object or person, among other forms or any combination thereof.

In some embodiments, the core sub-platform 120 may include a browser functionality, e.g., as an integration (e.g., Software-as-a-Service or other integration) linked to a browser object within the environment such as virtual representation of a doorway, lobby, computer, elevator, stairway, hallway, portal, or other real or imagined structure or any combination thereof. In some embodiments, the browser functionality may be called via user command, e.g., via selection of an interface elements, hotkey, key combination, or other input command or any combination thereof. In some embodiments, the browser functionality may provide mechanisms to navigate between and across microverses, 3D simulated spaces, macroverses and even to networks and network locations outside of the macroverses, such as traditional websites, search engines, social media, among others or any combination thereof. Navigation may include the user selection or actuation of interface elements that may include clicking a link, entering text, virtually moving (e.g., moving an avatar) towards an interface element associated with the desired network location, among other spatial and non-spatial interfacing modalities. For example, the browser object may be configured to present to the user a teleport or portal capability whereby a user may open a portal to another network location (e.g., based on a link, query, selection, etc.) and walk, via the avatar, through the portal to arrive at the desired network location.

In some embodiments, the browser functionality may be called via an object or location placed in the 3D simulated space, such as an item for purchase, a piece of art, a book or multimedia content item, or other object or any combination thereof. For example, where a user in a 3D simulated space associated with a store, the products represented therein may include links to other stores, review websites, search engines, social media, and/or other network locations. Upon approaching a product, the core sub-platform 120 may automatically create a space and/or a trigger in proximity to the product that allows the user to navigate to the other network location, such as by shifting or redefining the coordinate system to make space for a browser object to allow the user to enter and/or select the browser object.

In some embodiments, an object in the 3D simulated space may have attributes, such as metadata, associated therewith. A user navigating the 3D simulated space may trigger or otherwise use a browser object to initiate the browser functionality, which may automatically or on demand create a query for the attributes to search online for the object and/or similar objects. Additionally or alternatively, the user may trigger or otherwise use the browser object to enter a link (e.g., a URL or other network link) associated with the object. Whether by query or by link, the browser functionality may enable the user to browser the associated network location and/or locations, e.g., by entering or otherwise using the virtual representation associated with the browser object to browser network locations based on the object in the 3D simulated space.

In some embodiments, the browser functionality may include browsing network locations based on user input rather than or in addition to nearby objects in the 3D simulated space. For example, the user may enter into a text box or by voice command a URL, search query or other browser input, which may trigger a browser object to present browser functionality to navigate to the associated network location, e.g., via a doorway, hallway, tunnel, portal, lobby, etc.

In some embodiments, the browser object may include its own coordinate system within the hierarchical coordinate system such that the browser object can exist within the 3D simulated space with a scale that is independent of the scale of the 3D simulated space. Rather, the 3D simulated space may be adjusted in its own coordinate system to accommodate another object therein by creating a vacancy of predefined, configurable or dynamic size in the coordinate system of the 3D simulated space. The browser object may be placed in the vacancy with a size defined by the coordinate system of the browser object. The user, the entity associated with the location of the 3D simulated space, or other entity may define the size of the vacancy and/or browser object or any combination thereof.

In some embodiments, the core sub-platform 120 may include user focused features such as communication services, e.g., via plug-ins, add-ons, extensions, cloud services, or other integrations 110 for customer interaction with an owner and/or employee associated with the 3D simulated space. For example, the core sub-platform 120 may integrated with communication mechanisms such as, text prompts, chat windows, simulated telephones or intercoms for voice interactions or other interface elements which may appear as 2D and/or 3D interface elements within the 3D simulated space. The interface elements may appear as an overlay, a floating window, a 3D virtual object or person, among other forms or any combination thereof.

In some embodiments, the user focused tools include a workflow to create a store, create other 3D simulated space, and to define products to sell, advertise, link, etc.

In some embodiments, the retail focused tools may include tools to change or modify the design of the storefront, for example using a library of UI elements, types, styles, shadings, textures, etc. In some embodiments, the retail focused tools may include tools to add new retail spaces, either within the 3D simulated space (e.g., an “addition” or “expansion” to a storefront) or to create an addition 3D simulated space, e.g., in a different network location and/or different simulated location, or both.

In some embodiments, the core sub-platform 120 may provide the business, employee and/or business owner to rent, contract and/or sell space within the 3D simulated space, including all or a part of the 3D simulated space. Similarly, in some embodiments, the retail focused tools may include tools to link to other businesses and/or the 3D simulated spaces thereof, co-locate the 3D simulated space within a simulated or virtual location, create shared business spaces within the 3D simulated space, etc. Accordingly, the core sub-platform 120 may manage permissions and/or access to some or all of the tools of the core-sub-platform 120 for the 3D simulated space based on specification by the business, owner and/or employee associated with the 3D simulated space.

In some embodiments, the retail focused tools may include tools to use third party apps (e.g., the integrations 110) for retail uses, such as for pricing, investor management, bookkeeping, among other functions or any combination thereof.

In some embodiments, the retail focused tools may include tools to update products, manage products, introduce new products, change product locations, etc. For example, upon creating a store front and defining products in the store, the core sub-platform 120 may store the store front and/or product definitions and/or configurations in the data store(s) 160. The business, owner and/or employee may access the store front and/or product definitions and/or configurations in the data store(s) 160 to modify, add to, remove from, or otherwise change the store front and/or product definitions and/or configurations in the data store(s) 160.

In some embodiments, the business management focused tools may include incorporation of integrations 110 and/or native functionality to create management profiles and features associated with profiles, manage inventory (such as, e.g., a suite of third party apps via the integrations 110), manage and optimize products based on data analytics (e.g., using the data analytics sub-platform 150 as detailed below), manage employees and engage with employees, enable employees to engage with customers (such as, text prompts, chat windows, simulated telephones or intercoms for voice interactions or other interface elements which may appear as 2D and/or 3D interface elements within the 3D simulated space), use third party apps to increase productivity, management, etc. using third-party integrations 110, among other functionality or any combination thereof.

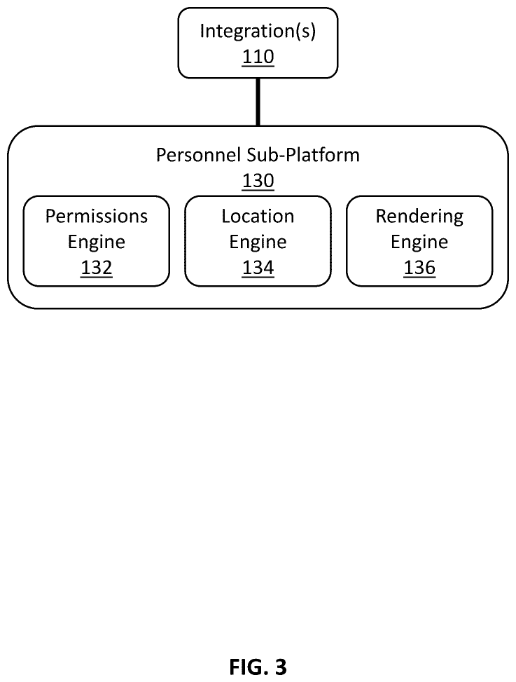

In some embodiments, the business employee focused tools may include profile management for employees, e.g., to enable employees to create their own profiles and features associated with profiles (e.g., via the personnel sub-platform 130 as detailed below with respect to FIG. 3), dynamically manage customer engagement at the 3D simulated space, manage employee to employee communications, coordination, collaborations among others, manage inventories, and/or use third party apps (e.g., in the integrations 110), among others or any combination thereof.

In some embodiments, the user sub-platform 140 may enable users outside of the organization associated with the 3D simulated space to engage with the 3D simulated space and engage with the organization such as with the business, owner and/or employees thereof.

In some embodiments, the user sub-platform 140 may enable management of a retail experience, such as creating a profile and/or avatar and adding features to the profile and/or avatar, manage user experiences in the stores (e.g., ad preferences, cookie permissions, 2D or 3D, etc.), manage a shopping cart and retail purchases, among others or any combination thereof.

In some embodiments, the user sub-platform 140 may enable management of user experiences in the 3D simulated space. For example, a user may create a space within the 3D simulated space to visit and congregate with others such the avatars of the other users (may be visible or non-visible to other users), request spaces to be created to increase user experiences, communicate with other users (such as, text prompts, chat windows, simulated telephones or intercoms for voice interactions or other interface elements which may appear as 2D and/or 3D interface elements within the 3D simulated space), co-experience, manage and link to third party apps (e.g., via the integration 110) for improving user experiences, among others or any combination thereof.

In some embodiments, the user sub-platform 140 may provide non-user created experiences with the 3D simulated environment. The non-user created experiences may be defined by the business, owner and/or employee, randomly determined and/or generated, or AI generated (e.g., using one or more ML models and/or large language models (LLMs) and/or generative AI). For example, the non-user created experiences may include additional non-playable characters based on predefined scripts, generative AI, or other techniques for developing non-playable characters. Similarly, the non-user created experiences may include additional events or occurrences within the 3D simulated space based on predefined scripts, generative AI, or other techniques for developing non-playable characters. The user sub-platform 140, therefore, may enable the system to have complete AI driven space and object creation abilities, independent of or in conjunction with user input, including the ability for users to see and incorporate these AI driven creative efforts using their respective sub-platforms.

In some embodiments, the data store(s) 160 may store configurations and definitions, such as object, simulated space, microverse, location, or other item definitions and/or configurations or any combination thereof. Similarly, the data store(s) 160 may store user activities, user presence statistics, user purchases, user profiles, among other user-related data or any combination thereof. In some embodiments, the data store(s) 160 may include analytics capabilities via data warehouses and/or lakes, cloud based Software-as-a-Service (SaaS) service (e.g., via the integrations 110) and/or native or local data storage and analytics resources.

In some embodiments, the data store(s) 160 may generate and visualize data. In some embodiments, the sub-platforms 120 through 150 may collect user activity and/or interaction data to generate user engagement/experience analytics, including and not limited to time related data, e.g. how much time did a customer spend looking at objects, how much time did a customer spend in a particular room, how closely did a customer look at an object, what objects are in the customer's peripheral vision, among others or any combination thereof.

In some embodiments, the data store(s) 160 may maintain databases and connect to data warehouses/lakes, including, e.g., creating separate databases for each of the group and/or category of user and/or data, such as personnel and/or client users, as well as associated personnel-related data and/or client user-related data. In some embodiments, the data store(s) 160 may maintain databases and connect to data warehouses/lakes depending on functionalities, such as spatial layout, object mechanisms, virtual object definitions and/or configurations, sales and inventory data, permissions, among other data or any combination thereof.

In some embodiments, the data store(s) 160 may import data from external databases, data warehouses and/or data lakes, or move data between internal databases, data warehouses and/or data lakes using extract-transform-load (ETL), extract-load-transform (ELT) (e.g., for data from cloud platforms). Thus, the data store(s) 160 may bring the data to data storage locations local to the 3D simulated space platform 100 thus providing an integrated systems effect that integrates data with the 3D simulated space platform 100.

In some embodiments, the data store(s) 160 may include data visualization tools, such as filters, sorting, list format, graphical format, data plot, progress bars, GANTT charts, among other visualization formats and tools. In some embodiments, the visualization tools may be interactive with a user, allowing for real-time and dynamic visualization and augmentation of data sets, such as selecting a graphical representation of a dataset and interacting with sorting and filtering tools to modify the data from the set presented in the graphical representation.

In some embodiments, the data analytics platform 150 may generate analytical insight from the data in the data store(s) 160, and may utilize graphical analyses, and descriptive, inferential, predictive statistical analyses, in addition to AI/ML methodologies. Again, we need to think of this in an integrated way that may enable use of optimal tech stacks and the latest AI/ML tools. In some embodiments, the data analytics platform 150 may access data in the data store(s) 160 to enable generation of new data and/or metrics, such as key performance indicators (KPIs), activity and behavior metrics, among other data or any combination thereof. In some embodiments, the data analytics platform 150 and/or the data source(s) 160 may collect and analyze the data from user activities in the 3D simulated space in real-time, and output dynamic or static data visualizations, reports, logs, among other data products or any combination thereof. In some embodiments, the visualizations, reports, logs, and other data products may be generated dynamically and in real-time, or may be generated as batch processes on a periodic basis (e.g., nightly, weekly, monthly, etc.).

In some embodiments, the data analytics platform 150 may provide data generation, storage and integration with real world analytics of the 3D simulated space for owners, managers, customers and employees. Such analytics may include business enterprise analytics software. In some embodiments, the analytics may be generated based on statistical modelling, algorithmic and/or programmatic analysis, machine learning such as deep neural networks, supervised learning, unsupervised learning, among other ML. As a result, the data analytics platform 150 may ingest data from the 3D simulated space and user activities therein to create new analytics, including four dimensional (4D) data generation that incorporates spatial data (e.g., within the 3D simulated space), time and/or a fourth dimension such as interaction cues, sentiment in an experiential sense, attention related data, among others or any combination thereof.

In some embodiments, the analytics may include business, owner and/or employee data as a well as client or customer user activity data. For example, personnel activity may be tracked and logged in the data store(s) 160, such as sales, employee achievements and productivity, customer activity, among other data associated with the 3D simulated space and activities therein. For example, the data analytics sub-platform 150 may track active versus inactive zones in the 3D simulated space. The 3D simulated space may be a virtual representation of a physical building or location, and thus personnel location and movement may be tracked in the 3D simulated space corresponding to movement in the real-world physical building or location. In some embodiments, such movement and/or location may be tracked via, e.g., sensors (e.g., Bluetooth®, RFID, NFC, tracking tags such a Bluetooth® or Airtag® trackers), image sensors, personnel availability and location indicators such as in enterprise or personnel chat and communication applications, among other ways of tracking location and/or movement or any combination thereof, to track employee activity. In some embodiments, the location and/or movement of personnel may be reflected in the 3D simulate space via avatars of the personnel and positioning thereof in locations within the 3D simulated space corresponding to the real-world physical locations.

In some embodiments, the data analytics platform 150 may track customer satisfaction/engagement/reviews gathered across the platform. The customer satisfaction/engagement/reviews may be gathered and made available in real time.

In some embodiments, the data analytics platform 150 may, using deep learning and ML, facilitate remediation and prediction. For example, if a manager wants to know how an employee is performing and where they need assistance in, the data analytics platform 150 may track task performance, task objective attainment, where shortcomings occur, and where potential remediation/assistance could occur. Deep learning could be used find better ways of completing tasks, etc., that can then be presented to the employee. Real time instruction could then be given using natural language feedback. Thus, the data analytics platform 150 may provide actionable insights and feedback.

In some embodiments, the data analytics platform 150 may include additional AI and/or ML enabled functionality. For example, as more users interact and create data in the 3D simulated space platform 100, an AI-enabled bot may learn consumer/owner behavior and generates new demand segments/products to create customer driven product offerings that at first might only exist virtually but could lead to completely innovative product offerings. Additionally, an AI-enabled bot may use employee behavior to identify and create “improvements” for processes.

In some embodiments, for the AI, ML and/or deep learning functionality, the data analytics platform 150 may be configured to utilize one or more exemplary AI/machine learning techniques chosen from, but not limited to, decision trees, boosting, support-vector machines, neural networks, nearest neighbor algorithms, Naive Bayes, bagging, random forests, and the like. In some embodiments and, optionally, in combination of any embodiment described above or below, an exemplary neutral network technique may be one of, without limitation, feedforward neural network, radial basis function network, recurrent neural network, convolutional network (e.g., U-net) or other suitable network. In some embodiments and, optionally, in combination of any embodiment described above or below, an exemplary implementation of Neural Network may be executed as follows:
i) define Neural Network architecture/model,
ii) transfer the input data to the exemplary neural network model,
iii) train the exemplary model incrementally,
iv) determine the accuracy for a specific number of timesteps,
v) apply the exemplary trained model to process the newly received input data,
vi) optionally and in parallel, continue to train the exemplary trained model with a predetermined periodicity.

In some embodiments and, optionally, in combination of any embodiment described above or below, the exemplary trained neural network model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the exemplary trained neural network model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the exemplary aggregation function may be a mathematical function that combines (e.g., sum, product, etc.) input signals to the node. In some embodiments and, optionally, in combination of any embodiment described above or below, an output of the exemplary aggregation function may be used as input to the exemplary activation function. In some embodiments and, optionally, in combination of any embodiment described above or below, the bias may be a constant value or function that may be used by the aggregation function and/or the activation function to make the node more or less likely to be activated.

In some embodiments, the sub-platforms 120 through 150 may include one or more additional sub-platforms, such as a blockchain platform. In some embodiments, the blockchain platform may enable a 3D simulated space platform 100 token to conduct transactions in the digital environment. The token may be based on a proprietary blockchain or adapt an existing one such as an Ethereum based blockchain. In some embodiments, the blockchain platform may be optional to the business, owner and/or employee. Where the business, owner and/or employee selects to integrate the blockchain platform and a token into the 3D simulated space, a token may be integrated that is common to all 3D simulated spaces on the 3D simulated space platform 100, common to one or more 3D simulate spaces, or is specific to the 3D simulate space of the business, owner and/or employee. As a result of the integration, users may conduct transactions using the token (denominated by dollars or other currency, goods, and/or services). The token may then be sold/traded on an exchange, issued as points/rewards for goods/services purchased in the 3D simulated space or used as in microverse currency or any combination thereof.

In some embodiments, the sub-platforms 120 through 150 may include one or more additional sub-platforms, such as a network “metaverse” that is a network of the microverses. This network may be built out to commercialize services aimed at giving insights to microverses on supply chain vulnerabilities, and other data insights that can be shared.

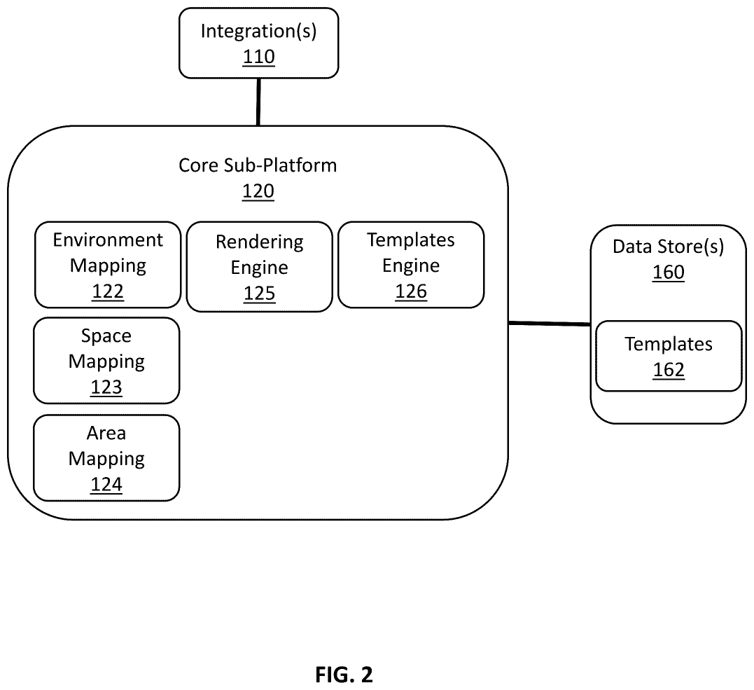

FIG. 2 depicts an illustrative core sub-platform 120 of the 3D simulated space platform 100 in accordance with one or more embodiment of the present disclosure.

In some embodiments, the core sub-platform 120 may include one or more computer engines for mapping a 3D simulated space to a virtual location, rendering the 3D simulated space in 2D, 3D or a combination thereof, and defining visual and/or functional features including integrations 110 via a library of templates 162 in the data store(s) 160. Thus, the core sub-platform 120 may include a structural programming language that is configured to define the virtual structure of an environment, space and/or area. The structural programming language may include, e.g., a markup language, object-orient programming language, scripting language, among others or any combination thereof.

As used herein, the terms “computer engine” and “engine” identify at least one software component and/or a combination of at least one software component and at least one hardware component which are designed/programmed/configured to manage/control other software and/or hardware components (such as the libraries, software development kits (SDKs), objects, etc.).

In some embodiments, the core sub-platform 120 may allow users/businesses to build a digital visual version of a real or imagined place (e.g., a place business or corporate HQ, or other physical place and/or structure, real or imagined) using the structural programming language and a variety of selectable templates 162 defining visual, structural and/or functional aspects, such as, e.g., a spatial layout, object color, texture, and/or pattern definitions, movement mechanics, visual locations and/or representations of integrations 110, and/or programming for interacting with the visual, structural and/or functional aspects. In some embodiments, a templates engine 126 may provide functionality for defining, modifying and/or loading templates 162 for a particular 3D simulated space to enable a user to define the 3D simulated space. In some embodiments, the templates engine 126 may also or instead provide functionality to manually define aspects of the 3D simulated space, such as by scanning in a digital version of an actual structure to build a digital model of an actual or imagined place of business/headquarters. Thus, the templates engine 126 may include a range of tools/options to enable a user to customize or select options/templates 162 based on the unique needs.

In some embodiments, the templates engine 126 may implement templates 162 for visual representation of the 3D simulated space as well as setup/experience to provide the option of getting up and running as simply and quickly as they like. In some embodiments, the selectable templates 162 may be provided as a convenience (e.g., as browsable packages) and for user ease. In some embodiments, the templates 162 may have embedded functionalities, such as being connected to data analytics sub-platform 150 and/or the data store(s) 160, as well as one or more of the integrations 110, e.g., via APIs and/or other computer interfaces. In some embodiments, the structural programming language may be used to create digital items, including digital items having predefined integrations with e.g., additional platform integrations, services, networks, artificial intelligence, among others or any combination thereof. The integrations may include third-party provided digital items that are configured to interface with the third-party functionality, e.g., including via an actuator designed to trigger or call the third-party functionality upon user interaction. Thus, by defining in the layout the positioning of a third-party digital item within an environment, space and/or area, the interface to the third-party functionality may be integrated into the environment, space and/or area. To do so, templates 162 may be defined on the platform that define the digital item, visual features of the digital item, one or more actuators for a user to interact with the digital item, one or more integrations with the third-party functionality, or other parameters or any combination thereof. Thus, as detailed herein, a template 162 may be applied to a space and/or area to create an integration that visually is presented as the defined digital item with functionalities according to the defined actuators and/or integrated third-party functionalities and/or services.

In some embodiments, a rendering engine 125 may use the configuration of the 3D simulated space, as defined by the selected templates 162 and/or user specification, to generate renderings in 2D and/or 3D of the 3D simulated space. In some embodiments, the rendering engine 125 may include options for view settings for all the whole or different sub-parts of structure and/or space such as top and side view 2D, as well first and third person 3D. For example, in some embodiments, the rendering engine 125 may give the user/owner/manager the option to engage in “player” mode if they wish: first person immersed, third person immersed, etc. and interact (visual/text/voice) in real time with the avatars/digital customers and employees. (real or NPC non-player character choices).

In some embodiments, the rendering engine 125 may generate the 3D simulated space in an unlimited space to showcase products (no end to end-caps) and/or an inside space/visual that does not match an outside visual of structure, enabled a 3D simulated space having a structure that is larger on an interior than an exterior, or vice versa. In some embodiments, the rendering engine 125 may provide for an ability to link/zoom to where products are sourced/made to showcase products. In some embodiments, the rendering engine 125 may enable the user, such as a business, owner, employee or client user to set one or more default views/initial log in settings/views or have the last view saved for next log in.

In some embodiments, the 3D simulated space may be accessed from one or more different device types via one or more of a web browser, web application, native application, or other form of delivery. Thus, the rendering engine 125 may include scaling tools to adapt the 3D simulated space to the delivery mechanism and output device. For example, the rendering engine 125 may scale the 3D simulated space in resolution, 2D and/or 3D components, and/or along any other scaling parameters to deliver the 3D simulated space to the user at the output device. For example, the business, owner and/or employee may define scaling settings such as, e.g., bandwidth/view/visual settings: if low bandwidth, 2D visual depiction while high bandwidth gets 3D visual depiction. In some embodiments, the rendering engine 125 may mix 2D and 3D elements to enable simultaneous 2D, 3D environments and features, and/or to include time-based experiences such as adaptation and variability in look, feel and/or layout, as well as experiences within the 3D simulated space.

Similarly, the rendering engine 125 may include scaling tools to adapt the 3D simulated space to the output device, such as multiple view and functionality versions/settings of platform to fit the different interaction hardware being used: mobile/desktop/laptop or virtual reality (VR), augmented reality (AR) and/or mixed reality (MR) headset. Thus, aspects of the 3D simulated space rendering, such as features, numbers of elements, textures, 2D and/or 3D objects, etc. may be adjusted to adapt the 3D simulated space to the speed/loading times and or feature limitations of the interaction hardware. Similarly, the tools may provide for offline versus online capabilities, such as through caching of objects, textures, or other components or any combination thereof.

In some embodiments, to build out a microverse, multiple 3D simulated spaces and/or multiple sub-spaces and/or structures within a 3D simulated space may be co-located in a virtual space, enable community and group features. For example, multiple scans and/or templates 162 may be used to provide retail store front, warehouse, manufacturing spaces, parking, etc. at a given virtual location. Alternatively, or in addition, the retail store front, warehouse, manufacturing spaces, parking, etc. may be separately located but linked, enabling a user to navigate from one space to the next based on in-microverse location definitions.

In some embodiments, an environment mapping engine 122 may manage the location definitions within the microverse, allowing for linking between virtual locations and/or co-locating structures and/or spaces within the 3D simulated space. Thus, multiple businesses can create a shared digital space for mutual marketing proximity partnerships with complimentary businesses in mutually agreed on digitally represented settings/landscapes (Small Town Main Street, Open Air Mall, Galleria or Urban Street, etc.) Can have multiple versions of digital business for multiple shared spaces/partnerships. In some embodiments, the core sub-platform 120 may apply a hierarchical coordinate systems to create a virtual environment in which multiple independent spaces may be placed, and which each space there may be multiple independent areas. To do so, the structural programming language may be used to configure an environment mapping 122, space mapping 123 and area mapping 124 based on an environment coordinate system, a space coordinate system and an area coordinate system, respectively. Thus, using the structural programming language, an administrator or other user permissioned to create, edit and/or delete virtual spaces, may define a layout according to the space coordinate system in order to create virtual space. The layout may include layout parameters including, according to the space coordinate system, e.g., exterior and interior dimensions, positioning of link-based actuators for linking to other virtual spaces, positioning of digital items, positioning of integrations 110, or rules regarding the placement, availability and/or visualization (e.g., size, orientation, etc.) of any one or more of the aforementioned layout parameters, among other layout parameters and/or layout parameter rules or any combination thereof. In some embodiments, the layout parameters may further include area parameters that define a size and/or shape of one or more areas in the area coordinate system, along with positioning, size and/or orientation of any digital items placed therein.

By using separate coordinate systems at different tiers of a hierarchy, each area and/or space need not be confined by the dimensions and/or size of other areas, spaces or the environment itself. Rather, the environment mapping 122 may apply the exterior layout parameters to cause the rendering engine 125 to present each space in the environment to a user in the environment but outside of the spaces as having positions and/or sizes based on the environment coordinate system. But upon virtually entering a space, e.g., via an avatar and/or first person view, the space mapping 123 may implement the layout parameters/rules to cause the rendering engine 125 to present to the user a space that is sized and shaped independent from its appearance in the environment. Similarly, the space mapping 123 may cause the rendering engine 125 to present areas within the space according to the space coordinate system until the area is entered, at which point the area mapping 124 may cause the rendering engine 125 to present the area as expanding in one or more dimensions, contracting in one or more dimensions or a combination thereof based on the area coordinate system of that area. Moreover, the user virtually entering an area or space may not remove another area or space from view, but rather maintain the relative positional relationship to the space or area that the user is in while the shape and/or size of the area changes.

In some embodiments, each of the environment mapping 122, the space mapping 123 and the area mapping 124 may responsively map elements of the environment, space(s) and/or area(s) based on user interactions and/or any other factors or any combination thereof. For example, each coordinate systems may be a dynamic coordinate system where the size and/or shape may change based on the contents. The contents themselves may be dynamic based on the user interaction, the time or day, day of the week, month of the year, administrator selection, or other factor or any combination thereof. Thus, in spaces and/or areas where digital items placed therein may vary, such as different store shelves, furniture, park or stage dimensions, or other digital items, the space and/or area may automatically expand or contract to fit the digital items. Such expansion or contraction may occur in real-time while a user is moving through the space/area, such as following a clothing rack that continually expands with additional offerings.

In some embodiments described herein, the spaces that appear within an environment and/or the areas that appear within a space may be dynamic based on the user, the time of day, the day of the week, the month of the year, an administrator selection, one or more integrations in an area or space, a user selection, among other factors or any combination thereof. In some embodiments, the structural programming language may be used to define rules regarding the behavior of the layout based on the factors, including user interaction. To do so, relational mappings may be defined in the layout using the structural programming language to define when and/or how two or more spaces are to appear in an environment together. The relational mappings may include conditional logic and/or machine learning inference to dynamically determine what spaces should appear in an environment together. For example, a user may navigate via an avatar to a particular space associated with a particular entity, and may be presented with the exterior of the space in an environment. Based on the user and one or more recommendations crafted for that user, other spaces of interest may also appear in the environment. Alternatively, or in addition, the particular entity may have an agreement with another entity to be co-located, universally or under certain conditions, and thus the space of the other entity may appear in the environment along with the particular space of the particular entity.

In some embodiments, each of the environment mapping 122, the space mapping 123 and the area mapping 124 may apply relational mappings that define relative positioning between spaces with respect to the environment coordinate system and/or between areas with respect to the space coordinate system. For example, the relationship mappings may define that one space is to be the right, left, front, back, on top of, beneath or any combination thereof relative to another space in the environment. In some embodiments, the relational mappings may define specific environment coordinates at which each space is to be positioned, or the relational mappings may define relative positioning (e.g., units to the left, right, behind, in front, beneath, above, etc.) between spaces.

In some embodiments, the locations may be user created and defined, including, e.g., analogs to actual locations on earth, or imagined such as Middle Earth, edge of the galaxy, etc. with view options such as first person or overview/side view and full globe map. As a result, the locations may inform the templates 162, allowing users to develop new templates 162 to share and/or sell to other users and enable other users to join or add to or link to an existing 3D simulated space.

In some embodiments, the environment mapping engine 122 may also reconcile user locations with 3D simulated space and microverse locations to enable users to populate the 3D simulated space, and to allow the business, owner and/or employee to define locations for actual or virtual customers and employees in the settings/backgrounds of their choice, e.g., urban, rural etc. using templates 162 or digital scans.

In some embodiments, to manage access, location and accessible features, the core sub-platform 120 may include options for scope/size/complexity of one or multiple accounts, including permissions to access, modify and/or interact with the 3D simulated space.

FIG. 3 depicts an illustrative personnel sub-platform 130 of the 3D simulated space platform 100 in accordance with one or more embodiment of the present disclosure.

In some embodiments, the personnel sub-platform 130 of the 3D simulated space platform 100 may provide functionality for employees or other permissioned non-owners of the 3D simulated space (e.g., “personnel”). In some embodiments, the personnel sub-platform 130 may include a permissions engine 132 to manage the permissions of such users to enable selected interaction capabilities for selected users based on user accounts and/or account types. In some embodiments, for example, the permissions engine 132 may be used to establish security settings for areas of general public/customers or different levels of access for employees and the external services different employees have access to. Similarly, the permissions engine 132 may be used to set managers and or general employee use or access controls for 3D simulated space platform 100 platform navigation, use, view and function management. (retail floor, graphic design floor, general office floor, etc.).

In some embodiments, the personnel sub-platform 130 may also include a location engine 134 that determines the location of personnel (e.g., the employees or other permissioned non-owners of the 3D simulated space). The location engine 134 may integrate with location and activity tracking cards of a real world space or structure and/or the 3D simulated space. In some embodiments, the virtual locations may track only in a given space. In some embodiments, there may be tracking across microverses, provide the permissions engine 132 determines that such permissions exist across locations. For example, the location engine 134 may integrate with physical sensors to track employee locations, e.g., with cards, to generate 4D locations to inform employee avatars in the microverse to merge real world and digital functions.

In some embodiments, the personnel may each have an avatar, or peruse in first person mode, or both. In some embodiments, the avatar may be presented to other users interacting with the 3D simulated space, and the avatar may be customizable based on the permissions engine 132.

In some embodiments, the location engine 134 may enable personnel to have the option to appear on the 3D simulated space if they choose or such a behavior may be set by a higher permissioned user. Accordingly, personnel may be anywhere, but when they log on through the personnel access, e.g., via the permissions engine 132, the permissions engine 132 may determine the personnel identity and level of access, and whether to depict, within the 3D simulated space using the avatar, that the personnel is at a workstation/office and/or the integrations 110 being used. In some embodiments, the location engine 134 may enable personnel to turn off tracking, but that action is seen by a master user such as the business and/or owner.

In some embodiments, a rendering engine 136, may be the same or different from the rendering engine 125, may provide for generating the visual representation of the 3D simulated space, including the avatars of the personnel.

In some embodiments, the rendering engine 136 may enable personnel to customize digital representations/avatars, digital office/workspace depending on permissions, among other visual preferences and configurations. Additionally, the rendering engine 136 may enable personnel to zoom out or zoom in with view options for macro or micro view of personnel “layer” of 3D simulated space platform 100 platform.

In some embodiments, the rendering engine 136 may create personnel social settings within the 3D simulated space by rendering community areas and events, such as, e.g., water coolers, breakrooms, without any design limits (e.g., a “holo deck”) as well some areas may be for general some for executives. Moreover, the rendering engine 136 may render on each personnel device, the avatars and activities of other personnel, including, e.g., depicting which personnel is helping which client user and “zoom” in to check on the interaction. In some embodiments, the observer of other personnel may be available to any other personnel or restricted to a particular user or set of users, such as a higher level employee, an owner of the business, or other user permissioned to do so. The observer may see the avatar, hear voice or view text or any combination thereof to monitor for quality control.

In some embodiments, the rendering engine 136 may integrate external or create internal more fluid/intuitive platform wide private and public voice, chat and vid options for personnel and managers, e.g., via the integrations 110. Similarly, the rendering engine 136 may enable integration 110 selections, e.g., via drag and drop, such as one or more of cross-marketed business support services like Google workplace, Slack chat, Drop Box, Liveplan, Quickbooks, among others or any combination thereof. Such integrations 110 may be represented in the 3D simulated space to the personnel as defined by the templates 162 and/or configurations defined by a user of the core sub-platform 120 as detailed above.

In some embodiments, the personnel sub-platform 130 may include one or more additional components and/or integrations such as AI-enabled functionality. For example, the personnel sub-platform 130 may include AI-based integration of task management/assignment, e.g., with infinite scrolling or other mechanics to improve immersion and productivity of the personnel. In such an example, the AI-based integration of task management/assignment may automatically identify and break down tasks into micro assignments to be surfaced dynamically to the personnel. As such, the AI-based integration may include AI-based task recognition and AI-based content recommendation to make the workflow and processes more manageable and instructive. The architecture may include Learning Management Systems, as well as real time scenario generation meant to improve task completion.

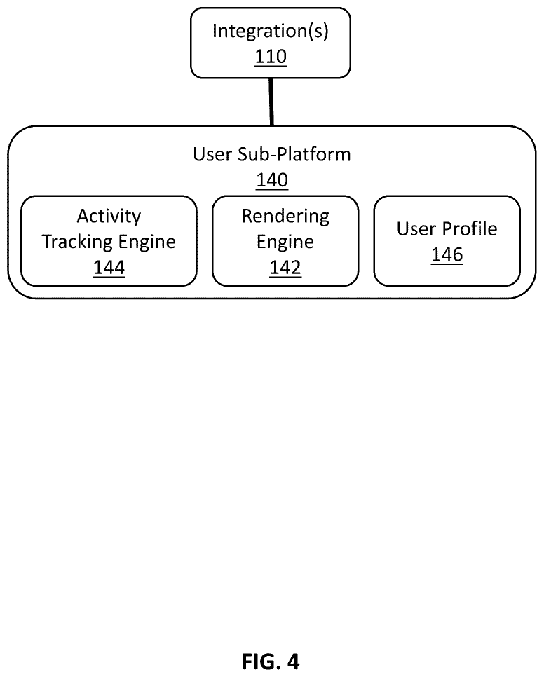

FIG. 4 depicts an illustrative user sub-platform 140 of the 3D simulated space platform 100 in accordance with one or more embodiment of the present disclosure.

In some embodiments, a rendering engine 142, may be the same or different from the rendering engine 125, may provide for generating the visual representation of the 3D simulated space, including the avatars of the client users.

In some embodiments, the rendering engine 142 may enable view options for how customers/clients view the 3D simulated space, which may be different or the same as the view and/or view options provided for personnel. Moreover, the rendering engine 142 may enable scaling between a website version and 3D rendered version, e.g., in a VR/AR/MR headset. For example, the scaling may default to a website version and scale up to a 3D version, or vice versa. Thus, the 3D simulated space may be accessed in browser mode, or desktop/mobile app. Data generated from interaction via the user interfaces may be gathered in databases, and ETLed to/in data warehouses/lakes.

In some embodiments, the rendering engine 142 may enable client users to create and/or participate in social spaces and or games/entertainment for client users to interact with or each other. Similarly, the rendering engine 142 may render waiting room and office visits in the visual digital version of business for interaction with clients based on configurations by the personnel and/or owner. In some embodiments, data on client user frequency, time spent, etc. may be tracked and the 3D simulated space platform 100 may automatically provide customize scheduling functionalities, accordingly, based on queuing theory for instance.

In some embodiments, the rendering engine 142 may provide full immersion of a product being browsed or other element of the 3D simulated space being interacted with, such as with pictures from one or more angles or digital visual version/representation of product or item. Thus, the rendering engine 142 may include a tool for 3D representations so there is a 3D model of the item within the virtual building, such as, e.g., Open AI's Point-E as an example of representation. In some embodiments, the rendering engine 142 may include 3D rotational capability (via quaternions).

In some embodiments, the rendering engine 142 may provide a history of where or how product/item was made or produced, provide supply chain linking to build a product based microverse made up of multiple businesses and or subsidiaries, provide digital visual representations of a shipping process as it unfolds, among other uses or any combination thereof. In some embodiments, the rendering engine 142 may enable a client user to teleport/zoom to the site or sites where a product is made (e.g., to tours of production areas) based on configurations as detailed above. Thus, client users may engage with a meta platform having an ability to connect microverses and businesses via networks.

In some embodiments, the rendering engine 142 may, if providing entertainment, music or sports viewing, enable business owners/managers to create digital visual representations of real or imagined venues big/grand or small for client users/fans to log in with their custom visual profile and enjoy live or prerecorded events (dependent on agreements with performer) in whatever seating arrangements they are assigned to in whatever arrangement is imagined/created depending on the situation curated for them by the owner/manager or if authorized by the performer.

In some embodiments, the rendering engine 142 may enable a personnel or owner defined ambiance for business setting: fountains, statues, art, music: real or AI performers or background playlists for pleasing atmosphere for client users/clients.

Moreover, the owner/manager can set view options (expand or limit) for client users that define how the rendering engine 142 renders the 3D simulated space and for whom.

In some embodiments, based on the mapping engine 122 detailed above, the rendering engine 142 may enable the client user to interact with other features such as co-location (virtually having two physical businesses side by side), product placement (other businesses can advertise products and services on someone else's site), product sampling like in a real store, client user behavior observation (witnessing what other store patrons are looking at), etc. For example, client users may view an object that could be represented in 3D, rotate the object, sample the object (e.g., by using the object in some way) or engage in any other interaction or any combination thereof. The rendering engine 142 may do so in 2D, 3D or via a holographic interface, such as a holographic projector. The holographic projector may include software that enables 3D printing, in addition to expedited physical shipping options. Because engagement and immersion is increased within the virtual model, the client user interest, sales, etc. may increase. In some embodiments, for example, the rendering engine 142 may depict instances of product placement based on AI-enabled content recommendation (e.g., placement in store or on shelf determined by how likely the shopper is to be interested). The product placement also or instead by defined by personnel and/or other permissioned users, such as advertisers, to place items innocuously in some other business as clients browse product offerings.

In some embodiments, the rendering engine 142 may render the 3D simulated space to a number of client users based on how many people can be fit in the space according to personnel configurations. The limit of how many can fit may cause some client users to be prevented from virtually entering the 3D simulated space, or may affect the number of users depicted as being in and/or interactable with in the 3D simulated space to each user. In some embodiments, the other client users that any particular client user sees and can interact with may be based on user privacy settings, contact lists, or other settings or any combination thereof.

In some embodiments, the user sub-platform 140 may include shopping tools to enable client users to shop for products and services in the 3D simulated space. For example, a activity tracking engine 144 may provide client users with a digital visual shopping cart as a 3D object to interact with or as another 2D and/or 3D element of the 3D simulated space. In some embodiments, the activity tracking engine 144 may also track user interaction with items in the 3D simulated space for data analytics, shopping analytics and other purposes.

In some embodiments, a user profile 146 may enable client users to create and save a custom visual digital version of their profile. The profile may include or be associated with the data collected, as detailed above, regarding user interactions with the 3D simulated space, for user by the data analytics sub-platform 150. Users can use an application or other mechanism to create a profile/avatar that can be used to create accounts with owners/businesses, which may be specific to each 3D simulated space or microverse, or universal to all microverses that have accounts with the 3D simulated space platform 100.

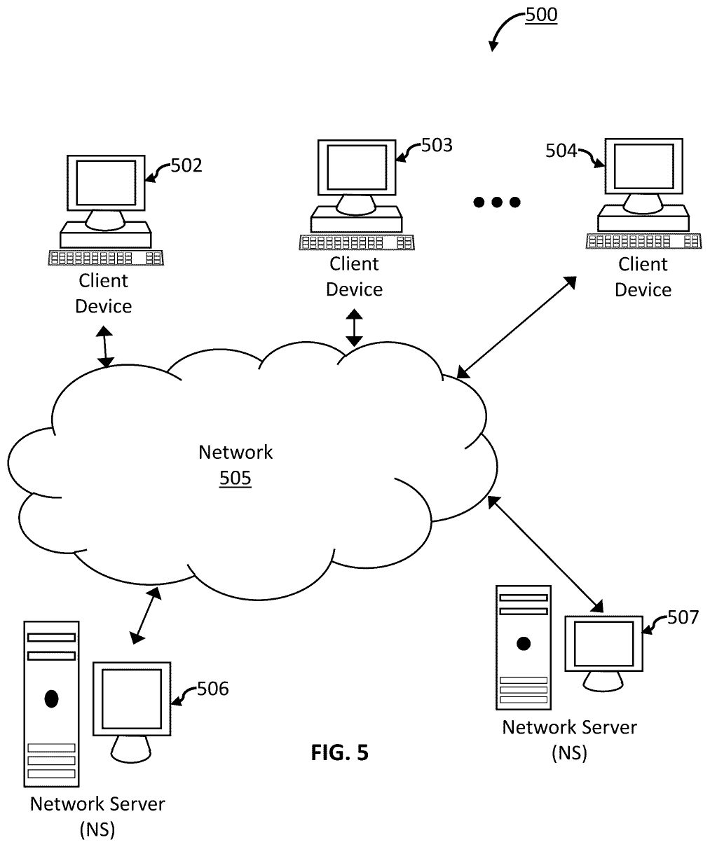

FIG. 5 depicts a block diagram of an exemplary computer-based system and platform 500 in accordance with one or more embodiments of the present disclosure. However, not all of these components may be required to practice one or more embodiments, and variations in the arrangement and type of the components may be made without departing from the spirit or scope of various embodiments of the present disclosure. In some embodiments, the illustrative computing devices and the illustrative computing components of the exemplary computer-based system and platform 500 may be configured to manage a large number of members and concurrent transactions, as detailed herein. In some embodiments, the exemplary computer-based system and platform 500 may be based on a scalable computer and network architecture that incorporates varies strategies for assessing the data, caching, searching, and/or database connection pooling. An example of the scalable architecture is an architecture that is capable of operating multiple servers.

In some embodiments, referring to FIG. 5, client device 502, client device 503 through client device 504 (e.g., clients) of the exemplary computer-based system and platform 500 may include virtually any computing device capable of receiving and sending a message over a network (e.g., cloud network), such as network 505, to and from another computing device, such as servers 506 and 507, each other, and the like. In some embodiments, the client devices 502 through 504 may be personal computers, multiprocessor systems, microprocessor-based or programmable consumer electronics, network PCs, and the like. In some embodiments, one or more client devices within client devices 502 through 504 may include computing devices that typically connect using a wireless communications medium such as cell phones, smart phones, pagers, walkie talkies, radio frequency (RF) devices, infrared (IR) devices, citizens band radio, integrated devices combining one or more of the preceding devices, or virtually any mobile computing device, and the like. In some embodiments, one or more client devices within client devices 502 through 504 may be devices that are capable of connecting using a wired or wireless communication medium such as a PDA, POCKET PC, wearable computer, a laptop, tablet, desktop computer, a netbook, a video game device, a pager, a smart phone, an ultra-mobile personal computer (UMPC), and/or any other device that is equipped to communicate over a wired and/or wireless communication medium (e.g., NFC, RFID, NBIOT, 3G, 4G, 5G, GSM, GPRS, WiFi, WiMax, CDMA, OFDM, OFDMA, LTE, satellite, ZigBee, etc.). In some embodiments, one or more client devices within client devices 502 through 504 may include may run one or more applications, such as Internet browsers, mobile applications, voice calls, video games, videoconferencing, and email, among others. In some embodiments, one or more client devices within client devices 502 through 504 may be configured to receive and to send web pages, and the like. In some embodiments, an exemplary specifically programmed browser application of the present disclosure may be configured to receive and display graphics, text, multimedia, and the like, employing virtually any web based language, including, but not limited to Standard Generalized Markup Language (SMGL), such as HyperText Markup Language (HTML), a wireless application protocol (WAP), a Handheld Device Markup Language (HDML), such as Wireless Markup Language (WML), WMLScript, XML, JavaScript, and the like. In some embodiments, a client device within client devices 502 through 504 may be specifically programmed by either Java, .Net, QT, C, C++, Python, PHP and/or other suitable programming language. In some embodiment of the device software, device control may be distributed between multiple standalone applications. In some embodiments, software components/applications can be updated and redeployed remotely as individual units or as a full software suite. In some embodiments, a client device may periodically report status or send alerts over text or email. In some embodiments, a client device may contain a data recorder which is remotely downloadable by the user using network protocols such as FTP, SSH, or other file transfer mechanisms. In some embodiments, a client device may provide several levels of user interface, for example, advance user, standard user. In some embodiments, one or more client devices within client devices 502 through 504 may be specifically programmed include or execute an application to perform a variety of possible tasks, such as, without limitation, messaging functionality, browsing, searching, playing, streaming or displaying various forms of content, including locally stored or uploaded messages, images and/or video, and/or games.

In some embodiments, the exemplary network 505 may provide network access, data transport and/or other services to any computing device coupled to it. In some embodiments, the exemplary network 505 may include and implement at least one specialized network architecture that may be based at least in part on one or more standards set by, for example, without limitation, Global System for Mobile communication (GSM) Association, the Internet Engineering Task Force (IETF), and the Worldwide Interoperability for Microwave Access (WiMAX) forum. In some embodiments, the exemplary network 505 may implement one or more of a GSM architecture, a General Packet Radio Service (GPRS) architecture, a Universal Mobile Telecommunications System (UMTS) architecture, and an evolution of UMTS referred to as Long Term Evolution (LTE). In some embodiments, the exemplary network 505 may include and implement, as an alternative or in conjunction with one or more of the above, a WiMAX architecture defined by the WiMAX forum. In some embodiments and, optionally, in combination of any embodiment described above or below, the exemplary network 505 may also include, for instance, at least one of a local area network (LAN), a wide area network (WAN), the Internet, a virtual LAN (VLAN), an enterprise LAN, a layer 3 virtual private network (VPN), an enterprise IP network, or any combination thereof. In some embodiments and, optionally, in combination of any embodiment described above or below, at least one computer network communication over the exemplary network 505 may be transmitted based at least in part on one of more communication modes such as but not limited to: NFC, RFID, Narrow Band Internet of Things (NBIOT), ZigBee, 3G, 4G, 5G, GSM, GPRS, WiFi, WiMax, CDMA, OFDM, OFDMA, LTE, satellite and any combination thereof. In some embodiments, the exemplary network 505 may also include mass storage, such as network attached storage (NAS), a storage area network (SAN), a content delivery network (CDN) or other forms of computer or machine readable media.

In some embodiments, the exemplary server 506 or the exemplary server 507 may be a web server (or a series of servers) running a network operating system, examples of which may include but are not limited to Apache on Linux or Microsoft IIS (Internet Information Services). In some embodiments, the exemplary server 506 or the exemplary server 507 may be used for and/or provide cloud and/or network computing. Although not shown in FIG. 5, in some embodiments, the exemplary server 506 or the exemplary server 507 may have connections to external systems like email, SMS messaging, text messaging, ad content providers, etc. Any of the features of the exemplary server 506 may be also implemented in the exemplary server 507 and vice versa.

In some embodiments, one or more of the exemplary servers 506 and 507 may be specifically programmed to perform, in non-limiting example, as authentication servers, search servers, email servers, social networking services servers, Short Message Service (SMS) servers, Instant Messaging (IM) servers, Multimedia Messaging Service (MMS) servers, exchange servers, photo-sharing services servers, advertisement providing servers, financial/banking-related services servers, travel services servers, or any similarly suitable service-base servers for users of the client devices 501 through 504.

In some embodiments and, optionally, in combination of any embodiment described above or below, for example, one or more exemplary computing client devices 502 through 504, the exemplary server 506, and/or the exemplary server 507 may include a specifically programmed software module that may be configured to send, process, and receive information using a scripting language, a remote procedure call, an email, a tweet, Short Message Service (SMS), Multimedia Message Service (MMS), instant messaging (IM), an application programming interface, Simple Object Access Protocol (SOAP) methods, Common Object Request Broker Architecture (CORBA), HTTP (Hypertext Transfer Protocol), REST (Representational State Transfer), SOAP (Simple Object Transfer Protocol), MLLP (Minimum Lower Layer Protocol), or any combination thereof.

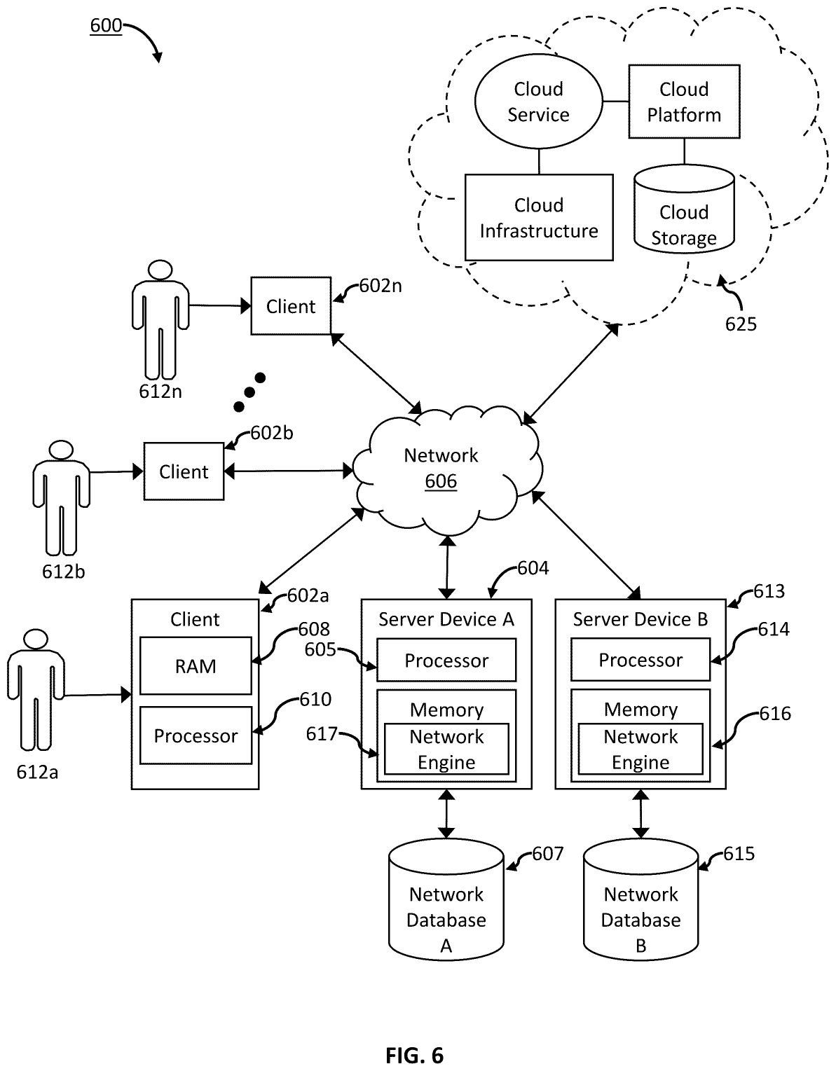

FIG. 6 depicts a block diagram of another exemplary computer-based system and platform 600 in accordance with one or more embodiments of the present disclosure. However, not all of these components may be required to practice one or more embodiments, and variations in the arrangement and type of the components may be made without departing from the spirit or scope of various embodiments of the present disclosure. In some embodiments, the client device 602a, client device 602b through client device 602n shown each at least includes a computer-readable medium, such as a random-access memory (RAM) 608 coupled to a processor 610 or FLASH memory. In some embodiments, the processor 610 may execute computer-executable program instructions stored in memory 608. In some embodiments, the processor 610 may include a microprocessor, an ASIC, and/or a state machine. In some embodiments, the processor 610 may include, or may be in communication with, media, for example computer-readable media, which stores instructions that, when executed by the processor 610, may cause the processor 610 to perform one or more steps described herein. In some embodiments, examples of computer-readable media may include, but are not limited to, an electronic, optical, magnetic, or other storage or transmission device capable of providing a processor, such as the processor 610 of client device 602a, with computer-readable instructions. In some embodiments, other examples of suitable media may include, but are not limited to, a floppy disk, CD-ROM, DVD, magnetic disk, memory chip, ROM, RAM, an ASIC, a configured processor, all optical media, all magnetic tape or other magnetic media, or any other medium from which a computer processor can read instructions. Also, various other forms of computer-readable media may transmit or carry instructions to a computer, including a router, private or public network, or other transmission device or channel, both wired and wireless. In some embodiments, the instructions may comprise code from any computer-programming language, including, for example, C, C++, Visual Basic, Java, Python, Perl, JavaScript, and etc.

In some embodiments, client devices 602a through 602n may also comprise a number of external or internal devices such as a mouse, a CD-ROM, DVD, a physical or virtual keyboard, a display, or other input or output devices. In some embodiments, examples of client devices 602a through 602n (e.g., clients) may be any type of processor-based platforms that are connected to a network 606 such as, without limitation, personal computers, digital assistants, personal digital assistants, smart phones, pagers, digital tablets, laptop computers, Internet appliances, and other processor-based devices. In some embodiments, client devices 602a through 602n may be specifically programmed with one or more application programs in accordance with one or more principles/methodologies detailed herein. In some embodiments, client devices 602a through 602n may operate on any operating system capable of supporting a browser or browser-enabled application, such as Microsoft™, Windows™, and/or Linux. In some embodiments, client devices 602a through 602n shown may include, for example, personal computers executing a browser application program such as Microsoft Corporation's Internet Explorer™, Apple Computer, Inc.'s Safari™, Mozilla Firefox, and/or Opera. In some embodiments, through the member computing client devices 602a through 602n, user 612a, user 612b through user 612n, may communicate over the exemplary network 606 with each other and/or with other systems and/or devices coupled to the network 606. As shown in FIG. 6, exemplary server devices 604 and 613 may include processor 605 and processor 614, respectively, as well as memory 617 and memory 616, respectively. In some embodiments, the server devices 604 and 613 may be also coupled to the network 606. In some embodiments, one or more client devices 602a through 602n may be mobile clients.

In some embodiments, at least one database of exemplary databases 607 and 615 may be any type of database, including a database managed by a database management system (DBMS). In some embodiments, an exemplary DBMS-managed database may be specifically programmed as an engine that controls organization, storage, management, and/or retrieval of data in the respective database. In some embodiments, the exemplary DBMS-managed database may be specifically programmed to provide the ability to query, backup and replicate, enforce rules, provide security, compute, perform change and access logging, and/or automate optimization. In some embodiments, the exemplary DBMS-managed database may be chosen from Oracle database, IBM DB2, Adaptive Server Enterprise, FileMaker, Microsoft Access, Microsoft SQL Server, MySQL, PostgreSQL, and a NoSQL implementation. In some embodiments, the exemplary DBMS-managed database may be specifically programmed to define each respective schema of each database in the exemplary DBMS, according to a particular database model of the present disclosure which may include a hierarchical model, network model, relational model, object model, or some other suitable organization that may result in one or more applicable data structures that may include fields, records, files, and/or objects. In some embodiments, the exemplary DBMS-managed database may be specifically programmed to include metadata about the data that is stored.

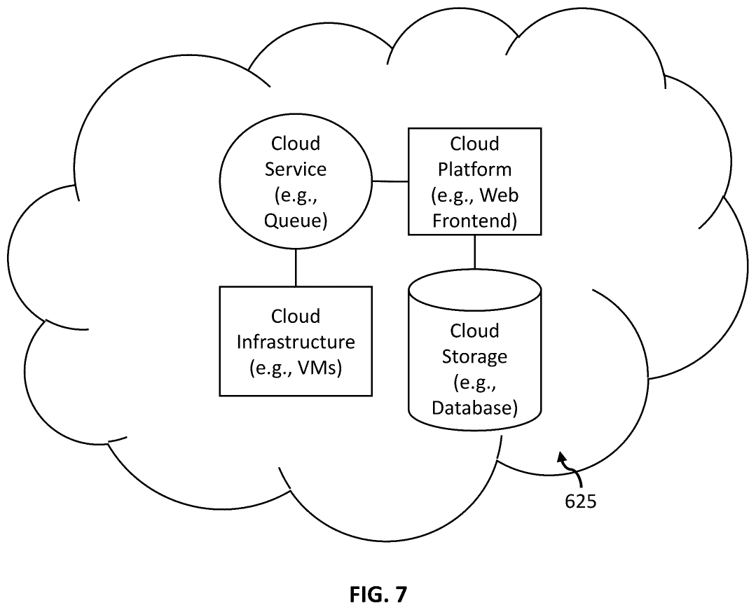

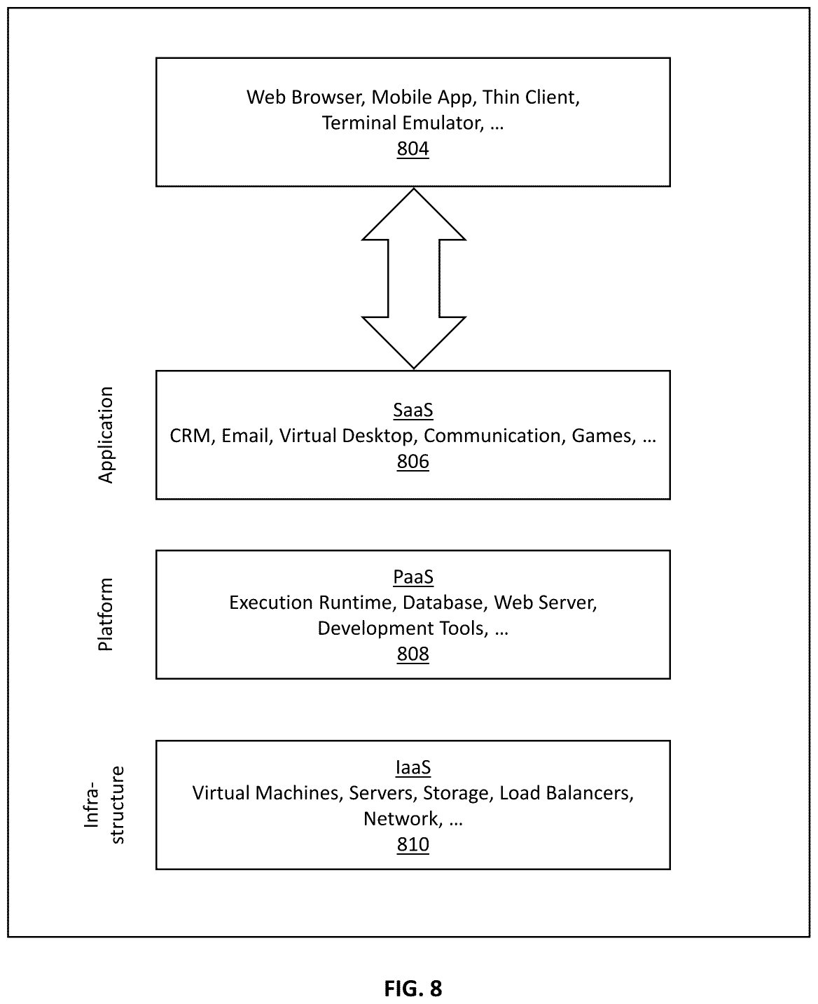

In some embodiments, the exemplary inventive computer-based systems/platforms, the exemplary inventive computer-based devices, and/or the exemplary inventive computer-based components of the present disclosure may be specifically configured to operate in a cloud computing/architecture 625 such as, but not limiting to: infrastructure a service (IaaS) 810, platform as a service (PaaS) 808, and/or software as a service (Saas) 806 using a web browser, mobile app, thin client, terminal emulator or other endpoint 804. FIGS. 7 and 8 illustrate schematics of exemplary implementations of the cloud computing/architecture(s) in which the exemplary inventive computer-based systems/platforms, the exemplary inventive computer-based devices, and/or the exemplary inventive computer-based components of the present disclosure may be specifically configured to operate.

It is understood that at least one aspect/functionality of various embodiments described herein can be performed in real-time and/or dynamically. As used herein, the term “real-time” is directed to an event/action that can occur instantaneously or almost instantaneously in time when another event/action has occurred. For example, the “real-time processing,” “real-time computation,” and “real-time execution” all pertain to the performance of a computation during the actual time that the related physical process (e.g., a user interacting with an application on a mobile device) occurs, in order that results of the computation can be used in guiding the physical process.

As used herein, the term “dynamically” and term “automatically,” and their logical and/or linguistic relatives and/or derivatives, mean that certain events and/or actions can be triggered and/or occur without any human intervention. In some embodiments, events and/or actions in accordance with the present disclosure can be in real-time and/or based on a predetermined periodicity of at least one of: nanosecond, several nanoseconds, millisecond, several milliseconds, second, several seconds, minute, several minutes, hourly, several hours, daily, several days, weekly, monthly, etc.

As used herein, the term “runtime” corresponds to any behavior that is dynamically determined during an execution of a software application or at least a portion of software application.

In some embodiments, exemplary inventive, specially programmed computing systems and platforms with associated devices are configured to operate in the distributed network environment, communicating with one another over one or more suitable data communication networks (e.g., the Internet, satellite, etc.) and utilizing one or more suitable data communication protocols/modes such as, without limitation, IPX/SPX, X.25, AX.25, AppleTalk™, TCP/IP (e.g., HTTP), near-field wireless communication (NFC), RFID, Narrow Band Internet of Things (NBIOT), 3G, 4G, 5G, GSM, GPRS, WiFi, WiMax, CDMA, satellite, ZigBee, and other suitable communication modes.

In some embodiments, the NFC can represent a short-range wireless communications technology in which NFC-enabled devices are “swiped,” “bumped,” “tap” or otherwise moved in close proximity to communicate. In some embodiments, the NFC could include a set of short-range wireless technologies, typically requiring a distance of 10 cm or less. In some embodiments, the NFC may operate at 13.56 MHz on ISO/IEC 18000-3 air interface and at rates ranging from 106 kbit/s to 424 kbit/s. In some embodiments, the NFC can involve an initiator and a target; the initiator actively generates an RF field that can power a passive target. In some embodiment, this can enable NFC targets to take very simple form factors such as tags, stickers, key fobs, or cards that do not require batteries. In some embodiments, the NFC's peer-to-peer communication can be conducted when a plurality of NFC-enable devices (e.g., smartphones) within close proximity of each other.

The material disclosed herein may be implemented in software or firmware or a combination of them or as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

As used herein, the terms “computer engine” and “engine” identify at least one software component and/or a combination of at least one software component and at least one hardware component which are designed/programmed/configured to manage/control other software and/or hardware components (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores,” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, etc.).

In some embodiments, one or more of illustrative computer-based systems or platforms of the present disclosure may include or be incorporated, partially or entirely into at least one personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

As used herein, term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud servers are examples.

In some embodiments, as detailed herein, one or more of the computer-based systems of the present disclosure may obtain, manipulate, transfer, store, transform, generate, and/or output any digital object and/or data unit (e.g., from inside and/or outside of a particular application) that can be in any suitable form such as, without limitation, a file, a contact, a task, an email, a message, a map, an entire application (e.g., a calculator), data points, and other suitable data. In some embodiments, as detailed herein, one or more of the computer-based systems of the present disclosure may be implemented across one or more of various computer platforms such as, but not limited to: (1) FreeBSD, NetBSD, OpenBSD; (2) Linux; (3) Microsoft Windows™; (4) OpenVMS™; (5) OS X (MacOS™); (6) UNIX™; (7) Android; (8) iOS™; (9) Embedded Linux; (10) Tizen™; (11) WebOS™; (12) Adobe AIR™; (13) Binary Runtime Environment for Wireless (BREW™); (14) Cocoa™ (API); (15) Cocoa™ Touch; (16) Java™ Platforms; (17) JavaFX™; (18) QNX™; (19) Mono; (20) Google Blink; (21) Apple WebKit; (22) Mozilla Gecko™; (23) Mozilla XUL; (24).NET Framework; (25) Silverlight™; (26) Open Web Platform; (27) Oracle Database; (28) Qt™; (29) SAP NetWeaver™; (30) Smartface™; (31) Vexi™; (32) Kubernetes™ and (33) Windows Runtime (WinRT™) or other suitable computer platforms or any combination thereof. In some embodiments, illustrative computer-based systems or platforms of the present disclosure may be configured to utilize hardwired circuitry that may be used in place of or in combination with software instructions to implement features consistent with principles of the disclosure. Thus, implementations consistent with principles of the disclosure are not limited to any specific combination of hardware circuitry and software. For example, various embodiments may be embodied in many different ways as a software component such as, without limitation, a stand-alone software package, a combination of software packages, or it may be a software package incorporated as a “tool” in a larger software product.

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

In some embodiments, illustrative computer-based systems or platforms of the present disclosure may be configured to handle numerous concurrent users that may be, but is not limited to, at least 100 (e.g., but not limited to, 100-999), at least 1,000 (e.g., but not limited to, 1,000-9,999), at least 10,000 (e.g., but not limited to, 10,000-99,999), at least 100,000 (e.g., but not limited to, 100,000-999,999), at least 1,000,000 (e.g., but not limited to, 1,000,000-9,999,999), at least 10,000,000 (e.g., but not limited to, 10,000,000-99,999,999), at least 100,000,000 (e.g., but not limited to, 100,000,000-999,999,999), at least 1,000,000,000 (e.g., but not limited to, 1,000,000,000-999,999,999,999), and so on.

In some embodiments, illustrative computer-based systems or platforms of the present disclosure may be configured to output to distinct, specifically programmed graphical user interface implementations of the present disclosure (e.g., a desktop, a web app., etc.). In various implementations of the present disclosure, a final output may be displayed on a displaying screen which may be, without limitation, a screen of a computer, a screen of a mobile device, or the like. In various implementations, the display may be a holographic display. In various implementations, the display may be a transparent surface that may receive a visual projection. Such projections may convey various forms of information, images, or objects. For example, such projections may be a visual overlay for a mobile augmented reality (MAR) application.

In some embodiments, illustrative computer-based systems or platforms of the present disclosure may be configured to be utilized in various applications which may include, but not limited to, gaming, mobile-device games, video chats, video conferences, live video streaming, video streaming and/or augmented reality applications, mobile-device messenger applications, and others similarly suitable computer-device applications.

As used herein, the term “mobile electronic device,” or the like, may refer to any portable electronic device that may or may not be enabled with location tracking functionality (e.g., MAC address, Internet Protocol (IP) address, or the like). For example, a mobile electronic device can include, but is not limited to, a mobile phone, Personal Digital Assistant (PDA), Blackberry™, Pager, Smartphone, or any other reasonable mobile electronic device.

As used herein, terms “proximity detection,” “locating,” “location data,” “location information,” and “location tracking” refer to any form of location tracking technology or locating method that can be used to provide a location of, for example, a particular computing device, system or platform of the present disclosure and any associated computing devices, based at least in part on one or more of the following techniques and devices, without limitation: accelerometer(s), gyroscope(s), Global Positioning Systems (GPS); GPS accessed using Bluetooth™; GPS accessed using any reasonable form of wireless and non-wireless communication; WiFi™ server location data; Bluetooth™ based location data; triangulation such as, but not limited to, network based triangulation, WiFi™ server information based triangulation, Bluetooth™ server information based triangulation; Cell Identification based triangulation, Enhanced Cell Identification based triangulation, Uplink-Time difference of arrival (U-TDOA) based triangulation, Time of arrival (TOA) based triangulation, Angle of arrival (AOA) based triangulation; techniques and systems using a geographic coordinate system such as, but not limited to, longitudinal and latitudinal based, geodesic height based, Cartesian coordinates based; Radio Frequency Identification such as, but not limited to, Long range RFID, Short range RFID; using any form of RFID tag such as, but not limited to active RFID tags, passive RFID tags, battery assisted passive RFID tags; or any other reasonable way to determine location. For ease, at times the above variations are not listed or are only partially listed; this is in no way meant to be a limitation.

As used herein, terms “cloud,” “Internet cloud,” “cloud computing,” “cloud architecture,” and similar terms correspond to at least one of the following: (1) a large number of computers connected through a real-time communication network (e.g., Internet); (2) providing the ability to run a program or application on many connected computers (e.g., physical machines, virtual machines (VMs)) at the same time; (3) network-based services, which appear to be provided by real server hardware, and are in fact served up by virtual hardware (e.g., virtual servers), simulated by software running on one or more real machines (e.g., allowing to be moved around and scaled up (or down) on the fly without affecting the end user).

In some embodiments, the illustrative computer-based systems or platforms of the present disclosure may be configured to securely store and/or transmit data by utilizing one or more of encryption techniques (e.g., private/public key pair, Triple Data Encryption Standard (3DES), block cipher algorithms (e.g., IDEA, RC2, RC5, CAST and Skipjack), cryptographic hash algorithms (e.g., MD5, RIPEMD-160, RTRO, SHA-1, SHA-2, Tiger (TTH), WHIRLPOOL, RNGs).

As used herein, the term “user” shall have a meaning of at least one user. In some embodiments, the terms “user”, “subscriber” “consumer” or “customer” should be understood to refer to a user of an application or applications as described herein and/or a consumer of data supplied by a data provider. By way of example, and not limitation, the terms “user” or “subscriber” can refer to a person who receives data provided by the data or service provider over the Internet in a browser session, or can refer to an automated software application which receives the data and stores or processes the data.

The aforementioned examples are, of course, illustrative and not restrictive.

Publications cited throughout this document are hereby incorporated by reference in their entirety. While one or more embodiments of the present disclosure have been described, it is understood that these embodiments are illustrative only, and not restrictive, and that many modifications may become apparent to those of ordinary skill in the art, including that various embodiments of the inventive methodologies, the illustrative systems and platforms, and the illustrative devices described herein can be utilized in any combination with each other. Further still, the various steps may be carried out in any desired order (and any desired steps may be added and/or any desired steps may be eliminated).

1. A method comprising:
receiving, by at least one processor, a simulation request comprising identifying a place to be simulated in at least one virtual environment having at least one virtual environment 3D coordinate system;
obtaining, by the at least one processor, at least one digital layout representing at least one layout of at least one area of a planned virtual space;
mapping, by the at least one processor, at least one area defined within the at least one digital layout to at least one simulated area in the virtual space based at least in part on a virtual space 3D coordinate system so as to create a simulated space comprising at least one simulated layout corresponding to the at least one area of the planned space;
wherein the virtual space 3D coordinate system is mapped to at least one position in the at least one virtual environment 3D coordinate system to locate the simulated space in the at least one virtual environment;
wherein the virtual space 3D coordinate system is configured to dynamically resize the simulated space independently of the at least one virtual environment 3D coordinate system in response to at least one user interaction with the simulated space;
determining, by the at least one processor, at least one activity associated with the at least one simulated area;
determining, by the at least one processor, at least one external software integration providing at least one external software function associated with performing the at least one activity;
generating, by the at least one processor, at least one digital object in the at least one simulated area corresponding to the at least one external integration, the at least one digital object comprising at least one computer instruction configured to integrate the at least one external software function into the at least one simulated area;
wherein the at least one digital object is configured to, upon interaction by a user in the virtual space, cause the at least one external integration to perform the at least one external software function associated with performing the at least one activity; and
publishing, by the at least one processor, the simulated space for access via at least one computing device.

2. The method of claim 1, further comprising:
generating, by the least one processor, a plurality of digital objects in the virtual space based at least in part on the at least one layout;
wherein the plurality of digital objects comprises at least one of:
furniture,
decorations,
fixtures,
furnishings,
a clothing rack,
store shelving,
a cash register, or
a vending machine.

3. The method of claim 1, wherein the at least one digital object corresponding to the at least one external integration comprises at least one of:
a cash register that integrates at least one payment service into the virtual space,
a mobile chat bot that integrates at least one artificial intelligence based chat service into the virtual space, or
at least one data analytics model that integrates at least one data analytics service for user behavior tracking into the virtual space.

4. The method of claim 2, further comprising:
determining, by the at least one processor, the at least one digital object associated with the at least one activity; and
modifying, by the at least one processor, the at least one digital object in the at least one simulated area to define the at least one external software integration so as to cause to appear that the at least one digital object provides the at least one external software function.

5. The method of claim 1, further comprising:
generating, by the at least one processor, a plurality of graphical layers visually representing the virtual space according to the at least one digital layout and the virtual space 3D coordinate system;
wherein the plurality of graphical layers are configured to be dynamically rendered based at least in part on at least one computing so as to visually mix at least one portion of the virtual space with a physical view of the simulated space.

6. The method of claim 2, further comprising:
determining, by the at least one processor, a view orientation of the user of the at least one computing device in the simulated space;
determining, by the at least one processor, at least one graphical layer associated with the at least one digital object in the at least on the simulated space;
positioning, on at least one display of the at least one computing device, by the at least one processor, the at least one graphical layer to align the simulated space with the at least one area corresponding to the planned space based at least in part on the view orientation; and
rendering, by the at least one processor, the at least one graphical layer so as to superimpose the at least one digital object within the view orientation of the simulated space.

7. The method of claim 1, further comprising:
determining, by the at least one processor, a simulated user location within the virtual space associated with at least one physical user location based at least in part on the mapping of the at least one simulated area of the simulated space; and
generating, by the at least one processor, a simulated user location representation representing the simulated user location within the simulated space so as to reflect the at least one physical user location.

8. The method of claim 7, further comprising:
receiving, by the at least one processor, a location indication from at least one mobile device associated with the user.

9. The method of claim 1, further comprising:
mapping, by the at least one processor, a second area to a second simulated area in the virtual environment based at least in part on the virtual space 3D coordinate system so as to create a second simulated space of a second place in the virtual environment.

10. The method of claim 1, wherein the place comprises a physical location of a commercial entity.

11. A system comprising:
at least one processor in communication with at least one non-transitory computer-readable medium having software instructions stored thereon, wherein, upon execution of the software instructions, the at least one processor is configured to perform a method comprising:
receiving a simulation request comprising identifying a place to be simulated in at least one virtual environment having at least one virtual environment 3D coordinate system;
obtaining at least one digital layout representing at least one layout of at least one area of a planned virtual space;
mapping at least one area defined within the at least one digital layout to at least one simulated area in the virtual space based at least in part on a virtual space 3D coordinate system so as to create a simulated space comprising at least one simulated layout corresponding to the at least one area of the planned space;
wherein the virtual space 3D coordinate system is mapped to at least one position in the at least one virtual environment 3D coordinate system to locate the simulated space in the at least one virtual environment;
wherein the virtual space 3D coordinate system is configured to dynamically resize the simulated space independently of the at least one virtual environment 3D coordinate system in response to at least one user interaction with the simulated space;
determining at least one activity associated with the at least one simulated area;
determining at least one external software integration providing at least one external software function associated with performing the at least one activity;
generating at least one digital object in the at least one simulated area corresponding to the at least one external integration, the at least one digital object comprising at least one computer instruction configured to integrate the at least one external software function into the at least one simulated area;
wherein the at least one digital object is configured to, upon interaction by a user in the virtual space, cause the at least one external integration to perform the at least one external software function associated with performing the at least one activity; and
publishing the simulated space for access via at least one computing device.

12. The system of claim 11, the method further comprising:
generating a plurality of digital objects in the virtual space based at least in part on the at least one layout;
wherein the plurality of digital objects comprises at least one of:
furniture,
decorations,
fixtures,
furnishings,
a clothing rack,
store shelving,
a cash register, or
a vending machine.

13. The system of claim 11, wherein the at least one digital object corresponding to the at least one external integration comprises at least one of:
a cash register that integrates at least one payment service into the virtual space,
a mobile chat bot that integrates at least one artificial intelligence based chat service into the virtual space, or
at least one data analytics model that integrates at least one data analytics service for user behavior tracking into the virtual space.

14. The system of claim 12, the method further comprising:
determining the at least one digital object associated with the at least one activity; and
modifying the at least one digital object in the at least one simulated area to define the at least one external software integration so as to cause to appear that the at least one digital object provides the at least one external software function.

15. The system of claim 11, the method further comprising:
generating a plurality of graphical layers visually representing the virtual space according to the at least one digital layout and the virtual space 3D coordinate system;
wherein the plurality of graphical layers are configured to be dynamically rendered based at least in part on at least one computing so as to visually mix at least one portion of the virtual space with a physical view of the place.

16. The system of claim 12, the method further comprising:
determining a view orientation of the user of the at least one computing device in the simulated space;
determining at least one graphical layer associated with the at least one digital object in the at least on the simulated space;
positioning, on at least one display of the at least one computing device the at least one graphical layer to align the simulated space with the at least one area corresponding to the planned space based at least in part on the view orientation; and
rendering the at least one graphical layer so as to superimpose the at least one digital object within the view orientation of the simulated space.

17. The system of claim 11, the method further comprising:
determining a simulated user location within the virtual space associated with at least one physical user location based at least in part on the mapping of the at least one simulated area of the simulated space; and
generating a simulated user location representation representing the simulated user location within the simulated space so as to reflect the at least one physical user location.

18. The system of claim 17, the method further comprising:
receiving a location indication from at least one mobile device associated with the user.

19. The system of claim 11, the method further comprising:
mapping a second area to a second simulated area in the virtual environment based at least in part on the virtual space 3D coordinate system so as to create a second simulated space of a second place in the virtual environment.

20. The system of claim 11, wherein the place comprises a physical location of a commercial entity.
